(19) United States
(12) Patent Application Publication
(10) Pub. No.: US 2026/0014662 A1
(43) Pub. Date: Jan. 15, 2026

(54) GRINDING APPARATUS, WORKPIECE GRINDING METHOD, AND CHIP MANUFACTURING METHOD

(71) Applicant: DISCO CORPORATION, Tokyo (JP)

(72) Inventor: Yohei Wakabayashi, Japan (JP)

(21) Appl. No.: 19/225,222

(22) Filed: Jun. 2, 2025

(30) Foreign Application Priority Data
Jul. 9, 2024 (JP) 2024-110013
Mar. 12, 2025 (JP) 2025-039238

(51) Int. Cl. B24B 37/013; B24B 37/04; H01L 21/304

(52) U.S. Cl. CPC B24B 37/013; B24B 37/042; H01L 21/304

(57) ABSTRACT

A grinding apparatus includes a chuck table rotatable about a table rotational axis, a grinding unit including a spindle having a grinding wheel fitted to a lower end thereof, an inclination adjusting unit that adjusts inclination of one of or both the table rotational axis and the spindle, a thickness measuring instrument that measures a thickness of a workpiece, and a controller, the controller including a necessary adjustment amount calculating section that calculates an adjustment amount necessary for adjustment of the inclination as a necessary adjustment amount in reference to thickness information of the workpiece being ground, an actual adjustment amount calculating section that calculates an actual adjustment amount by multiplying the necessary adjustment amount by an adjustment rate, and an adjustment control section that adjusts the inclination by the actual adjustment amount.

### BACKGROUND OF THE INVENTION

### Field of the Invention

The present invention relates to a grinding apparatus that holds a workpiece such as a semiconductor wafer by a chuck table and grinds and thins the workpiece held on the chuck table, a grinding method of grinding a workpiece by a grinding apparatus, and a chip manufacturing method of manufacturing chips by grinding and dividing a workpiece.

### Description of the Related Art

Device chips including devices such as integrated circuits (ICs) or large scale integration (LSI) chips are manufactured from a disk-shaped wafer. Individual device chips are obtained by arranging a plurality of devices on the top surface of the wafer, grinding and thinning the wafer from an undersurface side thereof, and dividing the wafer on a device basis.

The grinding of a workpiece such as the wafer is performed in a grinding apparatus (see Japanese Patent Laid-open No. 2009-141176). The grinding apparatus includes a chuck table that holds the workpiece; and a grinding unit that grinds the workpiece held by the chuck table. The grinding unit includes a grinding wheel to which grinding stones are fixed, the grinding stones being arranged annularly within a plane approximately parallel to a holding surface of the chuck table, and a spindle that serves as a rotary shaft when the grinding wheel is rotated. Further, the grinding apparatus can rotate the chuck table about a table rotational axis that passes through the center of the holding surface, and can rotate the grinding stones in an annular track by rotating the grinding wheel about the spindle. The workpiece is ground by the chuck table and the grinding wheel (spindle) being rotated and the grinding unit being lowered to thereby bring the rotating grinding stones into contact with the workpiece.

In order to obtain a workpiece that is thinned to a predetermined thickness with high accuracy and that has a uniform thickness at different positions, the grinding apparatus monitors the thickness of the different positions of the workpiece being ground, by using a thickness measuring instrument (see Japanese Patent Laid-open No. 2022-133006). Further, the inclination of the table rotational axis and the spindle or the like is adjusted in reference to information regarding the thickness of the different positions of the workpiece.

### SUMMARY OF THE INVENTION

It takes some time for an effect of the adjustment of the inclination of the table rotational axis or the like to be reflected in a thickness distribution of the workpiece after the adjustment is made. When the inclination of the table rotational axis or the like is readjusted in this transient period, an adjustment amount is likely to be excessive, and the thickness distribution of the workpiece is less likely to be uniform. In addition, excessive adjustment and excessive correction for the excessive adjustment are repeated. As a result, a rapid decrease and a slow decrease in the thickness of the workpiece being ground are repeated. A stable processing result is difficult to obtain when processing conditions and a processing process are thus unstable. Meanwhile, in a case where a wait is performed for the next adjustment each time until the effect of the adjustment is reflected in the thickness distribution of the workpiece, the number of adjustments that can be made during the grinding of the workpiece is decreased. Therefore, adjustment corresponding to processing conditions changing momently cannot be made, so that variations in the processing result are increased.

It is accordingly an object of the present invention to provide a grinding apparatus, a method of grinding a workpiece, a method of manufacturing a ground workpiece, and a chip manufacturing method of manufacturing chips by grinding and dividing a workpiece that can accurately and uniformly grind the workpiece to a predetermined thickness by moderately adjusting processing conditions while grinding the workpiece.

In accordance with an aspect of the present invention, there is provided a grinding apparatus for grinding a workpiece, the grinding apparatus including a chuck table having a holding surface capable of holding the workpiece, the chuck table being rotatable about a table rotational axis that penetrates a center of the holding surface, a grinding unit including a spindle having a grinding wheel fitted to a lower end thereof such that a lower surface of the grinding wheel having annularly arranged grinding stones on the lower surface faces the holding surface of the chuck table, the grinding unit being configured to grind the workpiece held by the chuck table by the grinding stones of the grinding wheel, a raising and lowering mechanism configured to raise and lower the spindle and the chuck table relative to each other, an inclination adjusting unit configured to adjust inclination of one of or both the table rotational axis and the spindle, a thickness measuring instrument configured to measure a thickness of the workpiece held by the chuck table, and a controller, the controller including a grinding control section configured to bring the spindle and the chuck table close to each other by the raising and lowering mechanism while rotating the chuck table holding the workpiece about the table rotational axis and rotating the grinding wheel of the grinding unit about the spindle, bring the grinding stones into contact with the workpiece held by the chuck table, and make the grinding unit grind the workpiece, a necessary adjustment amount calculating section configured to obtain thickness information of the workpiece being ground by the grinding unit, by using the thickness measuring instrument, and calculate an adjustment amount necessary for adjustment of the inclination, the adjustment being performed by the inclination adjusting unit, as a necessary adjustment amount, in reference to the thickness information, an actual adjustment amount calculating section configured to calculate an actual adjustment amount by multiplying the necessary adjustment amount calculated by the necessary adjustment amount calculating section by an adjustment rate, and an adjustment control section configured to adjust the inclination by the actual adjustment amount calculated by the actual adjustment amount calculating section, by controlling the inclination adjusting unit.

Preferably, the necessary adjustment amount calculating section calculates the necessary adjustment amount such that PID control of the inclination is performed in reference to the thickness information.

Alternatively, preferably, the necessary adjustment amount calculating section calculates the necessary adjustment amount such that P control of the inclination is performed in reference to the thickness information.

In addition, preferably, the actual adjustment amount calculating section determines the adjustment rate in reference to the thickness information or the necessary adjustment amount.

More preferably, the actual adjustment amount calculating section sets the adjustment rate to a first adjustment rate when a value indicating the thickness information or the necessary adjustment amount is higher than a selection threshold value, and sets the adjustment rate to a second adjustment rate lower than the first adjustment rate when the value is equal to or less than the selection threshold value.

In accordance with another aspect of the present invention, there is provided a grinding method of grinding a workpiece in a grinding apparatus, the grinding apparatus including a chuck table having a holding surface capable of holding the workpiece, the chuck table being rotatable about a table rotational axis that penetrates a center of the holding surface, and a grinding unit including a spindle having a grinding wheel fitted to a lower end thereof, the grinding wheel having annularly arranged grinding stones on a lower surface thereof, the grinding method including holding the workpiece by the chuck table by placing the workpiece on the holding surface of the chuck table, and after the holding, grinding the workpiece by rotating the chuck table about the table rotational axis and rotating the spindle, moving the chuck table and the spindle relative to each other in a direction of approaching each other, and bringing the grinding stones into contact with the workpiece, the grinding including obtaining thickness information of the workpiece being ground, calculating an adjustment amount necessary to adjust inclination of one of or both the table rotational axis and the spindle as a necessary adjustment amount in reference to the thickness information, calculating an actual adjustment amount by multiplying the necessary adjustment amount by an adjustment rate, and adjusting the inclination by the actual adjustment amount.

Preferably, the grinding calculates the necessary adjustment amount such that PID control of the inclination can be performed in reference to the thickness information.

Alternatively, preferably, the grinding calculates the necessary adjustment amount such that P control of the inclination can be performed in reference to the thickness information.

In addition, preferably, the grinding determines the adjustment rate in reference to the thickness information or the necessary adjustment amount.

More preferably, the grinding sets the adjustment rate to a first adjustment rate when a value indicating the thickness information or the necessary adjustment amount is higher than a selection threshold value and sets the adjustment rate to a second adjustment rate lower than the first adjustment rate when the value is equal to or less than the selection threshold value.

In accordance with a further aspect of the present invention, there is provided a ground workpiece manufacturing method of grinding a workpiece in a grinding apparatus, the grinding apparatus including a chuck table having a holding surface capable of holding the workpiece, the chuck table being rotatable about a table rotational axis that penetrates a center of the holding surface, and a grinding unit including a spindle having a grinding wheel fitted to a lower end thereof, the grinding wheel having annularly arranged grinding stones on a lower surface thereof, the grinding method including holding the workpiece by the chuck table by placing the workpiece on the holding surface of the chuck table, and manufacturing a ground workpiece by rotating the chuck table about the table rotational axis and rotating the spindle, moving the chuck table and the spindle relative to each other in a direction of approaching each other, bringing the grinding stones into contact with the workpiece, and grinding the workpiece, when bringing the grinding stones into contact with the workpiece and grinding the workpiece, the method obtaining thickness information of the workpiece being ground, calculating an adjustment amount necessary to adjust inclination of one of or both the table rotational axis and the spindle as a necessary adjustment amount in reference to the thickness information, calculating an actual adjustment amount by multiplying the necessary adjustment amount by an adjustment rate, and adjusting the inclination by the actual adjustment amount.

In accordance with a still further aspect of the present invention, there is provided a chip manufacturing method of manufacturing chips by grinding a workpiece in a grinding apparatus and dividing the workpiece, the grinding apparatus including a chuck table having a holding surface capable of holding the workpiece, the chuck table being rotatable about a table rotational axis that penetrates a center of the holding surface, and a grinding unit including a spindle having a grinding wheel fitted to a lower end thereof, the grinding wheel having annularly arranged grinding stones on a lower surface thereof, the chip manufacturing method including holding the workpiece by the chuck table by placing the workpiece on the holding surface of the chuck table, grinding the workpiece by rotating the chuck table about the table rotational axis and rotating the spindle, moving the chuck table and the spindle relative to each other in a direction of approaching each other, and bringing the grinding stones into contact with the workpiece, and manufacturing individual chips by unloading the ground workpiece from the grinding apparatus and dividing the ground workpiece, when bringing the grinding stones into contact with the workpiece and grinding the workpiece, the method obtaining thickness information of the workpiece being ground, calculating an adjustment amount necessary to adjust inclination of one of or both the table rotational axis and the spindle as a necessary adjustment amount in reference to the thickness information, calculating an actual adjustment amount by multiplying the necessary adjustment amount by an adjustment rate, and adjusting the inclination by the actual adjustment amount.

The grinding apparatus and the workpiece grinding method according to one aspect of the present invention adjust the inclination of one of or both the table rotational axis as a rotational axis of the chuck table and the spindle to which the grinding wheel is connected while grinding the workpiece by the grinding wheel. At this time, the thickness information of the workpiece being ground is obtained, an adjustment amount necessary to adjust the inclination is calculated as a necessary adjustment amount in reference to the thickness information, and an actual adjustment amount is calculated by multiplying the necessary adjustment amount by an adjustment rate. Further, the inclination is adjusted by the actual adjustment amount.

That is, when the necessary adjustment amount necessary to adjust the inclination is calculated, the inclination is not immediately adjusted by the necessary adjustment amount. The actual adjustment amount is calculated by multiplying the necessary adjustment amount by a predetermined adjustment rate, and the inclination is adjusted by the actual adjustment amount. In this case, a moderate adjustment rate is selected such that the inclination can be adjusted at a moderate speed and such that repetition of adjustment and correction of the adjustment does not occur. It is thus possible to reduce variations in a processing result and the like that accompany the adjustment of the inclination.

Hence, according to one aspect of the present invention, there are provided a grinding apparatus, a method of grinding a workpiece, a method of manufacturing a ground workpiece, and a chip manufacturing method of manufacturing chips by grinding and dividing a workpiece which can accurately and uniformly grind the workpiece to a predetermined thickness by moderately adjusting processing conditions while grinding the workpiece.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating a grinding apparatus and a workpiece;

FIG. 2 is a sectional view schematically illustrating a grinding unit and a chuck table;

FIG. 3 is a plan view schematically illustrating a positional relation between the chuck table and a grinding wheel;

FIG. 4A is a graph schematically illustrating one element of thickness information of the workpiece;

FIG. 4B is a graph schematically illustrating another element of the thickness information of the workpiece;

FIG. 5A is a graph illustrating changes in a V amount in a case where an adjustment rate Kp was set at 0.0;

FIG. 5B is a graph illustrating changes in the V amount in a case where the adjustment rate Kp was set at 0.2;

FIG. 6A is a graph illustrating changes in the V amount in a case where the adjustment rate Kp was set at 0.3;

FIG. 6B is a graph illustrating changes in the V amount in a case where the adjustment rate Kp was set at 0.4;

FIG. 7A is a graph illustrating changes in the V amount in a case where the adjustment rate Kp was set at 0.5;

FIG. 7B is a graph illustrating changes in the V amount in a case where the adjustment rate Kp was set at 1.0;

FIG. 8 is a graph illustrating changes in the V amount in a case where the adjustment rate Kp was determined under a comparative condition;

FIG. 9A is a graph illustrating changes in the V amount in a case where the adjustment rate Kp was determined under a first condition;

FIG. 9B is a graph illustrating changes in the V amount in a case where the adjustment rate Kp was determined under a second condition;

FIG. 10 is a flowchart illustrating a flow of steps of a method of grinding the workpiece;

FIG. 11 is a flowchart illustrating a flow of steps of a manufacturing method of manufacturing a ground workpiece;

FIG. 12 is a flowchart illustrating a flow of steps of a method of manufacturing chips; and

FIG. 13 is a perspective view schematically illustrating a manner in which chips are manufactured by dividing the workpiece.

### DETAILED DESCRIPTION OF THE PREFERRED EMBODIMENT

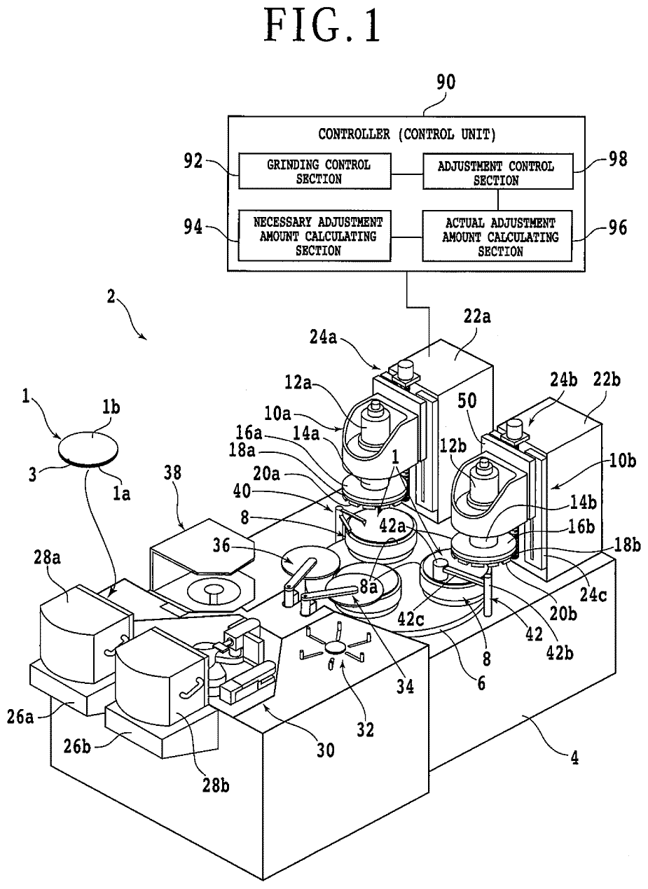

An embodiment according to the present invention will be described with reference to the drawings. A grinding apparatus according to the present embodiment thins a workpiece by grinding the workpiece. First, the workpiece will be described. FIG. 1 includes a perspective view schematically illustrating a workpiece 1. The workpiece 1 is, for example, a substantially disk-shaped wafer or the like formed of a material such as Si (silicon), SiC (silicon carbide), GaN (gallium nitride), GaAs (gallium arsenide), or another semiconductor. However, the workpiece 1 is not limited to this. Individual device chips are obtained by arranging a plurality of devices in a matrix form on a top surface 1a of the workpiece 1 such as a disk-shaped wafer, and dividing the workpiece 1 on a device basis. At this time, if the workpiece 1 is thinned in advance by grinding the workpiece 1 from an undersurface 1b side in a grinding apparatus 2 in advance, thin device chips are finally obtained. A tape-shaped protective member 3 that protects the devices formed on the top surface 1a and the like is affixed to the top surface 1a side of the workpiece 1 that is to be ground by the grinding apparatus 2.

Next, the grinding apparatus 2 according to the present embodiment will be described in detail. The grinding apparatus 2 includes a base 4 that supports various constituent elements. Cassette mounting bases 26a and 26b are fixed to a front end of the base 4. The cassette mounting bases 26a and 26b are mounted with cassettes 28a and 28b that house a plurality of workpieces 1. Further, in the grinding apparatus 2, workpieces 1 are extracted from the cassettes 28a and 28b one after another, the workpieces 1 are ground, and the ground workpieces 1 are housed in the cassettes 28a and 28b again. A wafer transfer robot 30 is installed at a position adjacent to the cassette mounting bases 26a and 26b on the base 4. The wafer transfer robot 30 unloads a workpiece 1 from the cassettes 28a and 28b mounted on the cassette mounting bases 26a and 26b, and transfers the workpiece 1 to a positioning table 32 provided at a position adjacent to the wafer transfer robot 30 on the base 4. The positioning table 32 has a plurality of positioning pins that are arranged in an annular manner. When the workpiece 1 is mounted in a central mounting region of the positioning table 32, the positioning table 32 positions the workpiece 1 at a planned position by moving each of the positioning pins radially inward in an interlocked manner.

A loading arm 34 and an unloading arm 36 are provided at positions adjacent to the positioning table 32 on the upper surface of the base 4. The loading arm 34 transfers the workpiece 1 positioned at the planned position by the positioning table 32. A disk-shaped turntable 6 is provided to the upper surface of a center of the base 4 in such a manner as to be rotatable within a horizontal plane. The upper surface of the turntable 6 is provided with three chuck tables 8 separated from each other by 120 degrees in a circumferential direction. Each of the chuck tables 8 for holding the workpiece 1 can be moved by rotation of the turntable 6.

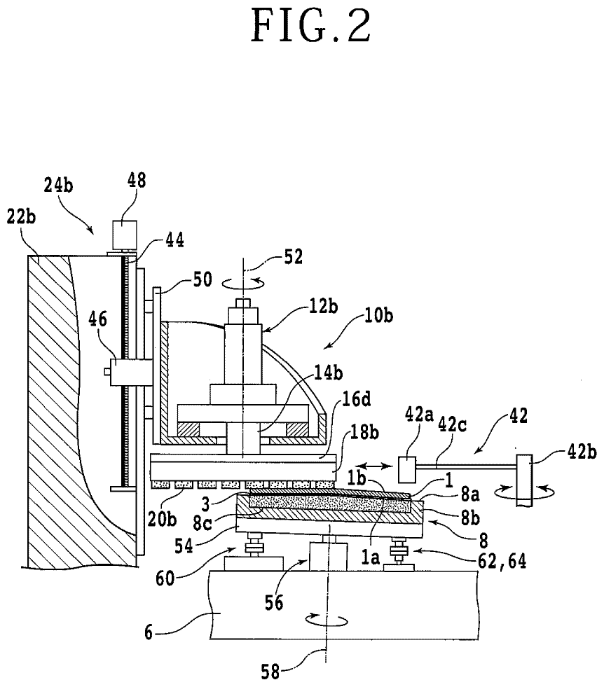

FIG. 2 includes a sectional view schematically illustrating a chuck table 8. The chuck table 8 includes a disk-shaped porous member 8c that has a diameter similar to that of the workpiece 1, and a frame body 8b made of stainless steel in which a recessed portion housing the porous member 8c is exposed upward. The frame body 8b of the chuck table 8 is provided with a suction passage one end of which reaches the bottom surface of the recessed portion. A suction source (not illustrated) is connected to another end of the suction passage. When the workpiece 1 is placed on the porous member 8c of the chuck table 8 and the suction source is actuated, a negative pressure acts on the workpiece 1 via the suction passage and the porous member 8c to hold under suction the workpiece 1 on the chuck table 8. That is, the upper surface of the chuck table 8 constitutes a holding surface 8a that holds the workpiece 1. The holding surface 8a is in the shape of a circular conical surface having a very gentle inclination, as will be described later.

In addition, a rotational driving source 56 such as a motor is connected to a bottom portion of the chuck table 8. The chuck table 8 can thereby be rotated about a table rotational axis 58 set in such a manner as to penetrate the center of the holding surface 8a. In addition, the bottom portion 54 of the chuck table 8 is supported by a plurality of supporting shafts in such a manner as not to be hindered from rotating, and one or a plurality of supporting shafts thereof are extensible and contractible. For example, in the grinding apparatus 2 according to the present embodiment, the bottom portion 54 of the chuck table 8 is supported by one fixed shaft 60 and two extensible and contractible adjusting shafts 62 and 64. Further, an inclination of the holding surface 8a (inclination of the table rotational axis 58) can be changed by adjusting the lengths of these adjusting shafts 62 and 64. That is, the adjusting shafts 62 and 64 function as an inclination adjusting unit that adjusts the inclination of the table rotational axis 58.

The description will be continued by returning to FIG. 1. The loading and unloading of the workpiece 1 onto and from the chuck table 8 is performed in a wafer loading and unloading region of the turntable 6. In the wafer loading and unloading region, the loading arm 34 can load the workpiece 1 onto the chuck table 8, and the unloading arm 36 can unload the workpiece 1 from the chuck table 8. After the loading arm 34 loads the workpiece 1 onto the chuck table 8 positioned in the wafer loading and unloading region, the turntable 6 is rotated to move the chuck table 8 to the next rough grinding region.

A first grinding unit 10a that roughly grinds the undersurface 1b of the workpiece 1 held on the chuck table 8 positioned in the rough grinding region is disposed on an outer side of the turntable 6 on the upper surface of a rear side of the base 4. After the first grinding unit 10a roughly grinds the workpiece 1, the turntable 6 is rotated to move the chuck table 8 to a finish grinding region adjacent to the rough grinding region.

A second grinding unit 10b that finish-grinds the undersurface 1b of the workpiece 1 held on the chuck table 8 positioned in the finish grinding region is disposed on the outer side of the turntable 6 on the upper surface of the rear side of the base 4. After the second grinding unit 10b performs the finish grinding of the workpiece 1, the turntable 6 is rotated to return the chuck table 8 to the wafer loading and unloading region, and the unloading arm 36 unloads the workpiece 1 from the chuck table 8.

A spinner cleaning apparatus 38 that cleans and spin-dries the ground workpiece 1 is disposed in the vicinity of the unloading arm 36 on the upper surface of the base 4 and the wafer transfer robot 30. Further, the workpiece 1 cleaned and dried by the spinner cleaning apparatus 38 is transferred from the spinner cleaning apparatus 38 by the wafer transfer robot 30, and is housed into the cassette 28a or 28b mounted on the cassette mounting base 26a or 26b.

Columns 22a and 22b are erected from a rear portion of the base 4. The first grinding unit 10a is disposed on the front surface of the column 22a in a raisable and lowerable manner. The second grinding unit 10b is disposed on the front surface of the column 22b in a raisable and lowerable manner. The first grinding unit 10a includes a first spindle 14a extending substantially along a vertical direction and a spindle motor 12a connected to an upper end of the first spindle 14a. In addition, the second grinding unit 10b includes a second spindle 14b extending substantially along the vertical direction and a spindle motor 12b connected to an upper end of the second spindle 14b.

The first grinding unit 10a includes a first raising and lowering mechanism 24a that supports, in a movable manner, constituent elements of the first grinding unit 10a including the first spindle 14a substantially along the vertical direction. The second grinding unit 10b includes a second raising and lowering mechanism 24b that supports, in a movable manner, constituent elements of the second grinding unit 10b including the second spindle 14b substantially along the vertical direction. Incidentally, in the grinding apparatus 2, the orientation of each of the spindles 14a and 14b may be adjustable in place of the table rotational axis 58. Alternatively, the orientation of each of the spindles 14a and 14b may be adjustable in addition to the table rotational axis 58. In other words, the grinding apparatus 2 includes an inclination adjusting unit that adjusts the inclination of one of or both the table rotational axis 58 and the spindle 14a or 14b.

FIG. 1 and FIG. 2 schematically illustrate the second raising and lowering mechanism 24b. The second raising and lowering mechanism 24b includes a pair of guide rails 24c provided along the vertical direction on the front surface of the column 22b, a raising and lowering plate 50 slidably supported by the guide rails 24c, and a ball screw 44 parallel to the pair of guide rails 24c. The constituent elements of the second grinding unit 10b are supported on the front surface side of the raising and lowering plate 50. A nut portion 46 is provided to the back surface side of the raising and lowering plate 50. This nut portion 46 has the ball screw 44 screwed therein. A pulse motor 48 is connected to an upper end of the ball screw 44. When the pulse motor 48 is actuated, the ball screw 44 is rotated, and the raising and lowering plate 50 is raised or lowered. The first raising and lowering mechanism 24a is configured in a manner similar to that of the second raising and lowering mechanism 24b. Incidentally, the raising and lowering mechanism of the grinding apparatus 2 may raise and lower the chuck table 8 in place of the spindles 14a and 14b, or may raise and lower the chuck table 8 in addition to the spindles 14a and 14b. In other words, the grinding apparatus 2 includes a raising and lowering mechanism that raises and lowers the spindle 14a or 14b and the chuck table 8 relative to each other.

A lower end of the first spindle 14a is provided with a disk-shaped wheel mount 16a. A first grinding wheel 18a is fixed to the lower surface of the wheel mount 16a. That is, the first grinding wheel 18a is fixed to the lower end of the first spindle 14a. A surface (lower surface) of the first grinding wheel 18a that faces the holding surface 8a of the chuck table 8 positioned in the rough grinding region is fitted with a plurality of first grinding stones 20a arranged annularly. A lower end of the second spindle 14b is provided with a disk-shaped wheel mount 16b. A second grinding wheel 18b is fixed to the lower surface of the wheel mount 16b. That is, the second grinding wheel 18b is fixed to the lower end of the second spindle 14b. A surface (lower surface) of the second grinding wheel 18b that faces the holding surface 8a of the chuck table 8 positioned in the finish grinding region is fitted with a plurality of second grinding stones 20b arranged annularly.

When the first spindle 14a is rotated by the spindle motor 12a being actuated, the first grinding wheel 18a rotates, and the first grinding stones 20a move in a first annular track. Then, the workpiece 1 is ground when the first spindle 14a is lowered by the raising and lowering mechanism 24a being actuated and the first grinding stones 20a are brought into contact with the undersurface 1b (upper surface) of the workpiece 1 held on the chuck table 8. In addition, when the spindle 14b is rotated by the spindle motor 12b being actuated, the second grinding wheel 18b rotates, and the second grinding stones 20b move in a second annular track. Then, the workpiece 1 is ground when the second spindle 14b is lowered by the raising and lowering mechanism 24b being actuated and the second grinding stones 20b are brought into contact with the undersurface 1b (upper surface) of the workpiece 1 held on the chuck table 8.

The first grinding unit 10a performs grinding feed by the raising and lowering mechanism 24a at a relatively fast speed, and roughly grinds the workpiece 1. The rough grinding by the first grinding unit 10a removes most of a total grinding amount before a finished thickness of the workpiece 1 is reached. The second grinding unit 10b performs grinding feed by the raising and lowering mechanism 24b at a relatively low speed, and finish-grinds the workpiece 1. The finish grinding by the second grinding unit 10b grinds the workpiece 1 until the finished thickness is reached, and the finish grinding removes roughness on the undersurface 1b side. The first grinding stones 20a and the second grinding stones 20b include abrasive grains formed by diamond or the like and a binder that disperses and fixes the abrasive grains. The second grinding stones 20b used for the finish grinding preferably include abrasive grains having a particle diameter smaller than the particle diameter of the abrasive grains included in the first grinding stones 20a used for the rough grinding. In this case, the first grinding stones 20a can roughly grind the workpiece 1 quickly, while the second grinding stones 20b can finish-grind the workpiece 1 with high quality.

A first thickness measuring instrument 40 for measuring the thickness of the workpiece 1 roughly ground by the first grinding unit 10a is disposed in the vicinity of the first grinding unit 10a on the upper surface of the base 4. A second thickness measuring instrument 42 for measuring the thickness of the workpiece 1 finish-ground by the second grinding unit 10b is disposed in the vicinity of the second grinding unit 10b on the upper surface of the base 4.

The first thickness measuring instrument 40 is, for example, a contact-type thickness measuring instrument that comes into contact with the undersurface 1b of the workpiece 1. The contact-type thickness measuring instrument includes, for example, two probes extending above the chuck table 8. Each of the probes includes a contact portion that extends downward from a distal end of an arm portion extending in a horizontal direction. One probe measures the height of the undersurface 1b of the workpiece 1 by bringing a lower end of the contact portion into contact with the undersurface 1b of the workpiece 1. Meanwhile, the other probe measures the height of the holding surface 8a by bringing a lower end of the contact portion into contact with the holding surface 8a of the chuck table 8. The workpiece 1 is placed and held on the holding surface 8a of the chuck table 8 via the protective member 3. The contact-type thickness measuring instrument can thus calculate a total thickness of the workpiece 1 and the protective member 3 from a difference between the measured height of the undersurface 1b of the workpiece 1 and the measured height of the holding surface 8a of the chuck table 8.

In addition, the second thickness measuring instrument 42 is, for example, a noncontact-type thickness measuring instrument that does not come into physical contact with the undersurface 1b of the workpiece 1. The noncontact-type thickness measuring instrument measures the height of the undersurface 1b of the workpiece 1 by, for example, sending an ultrasonic wave or probe light to the undersurface 1b from a measuring unit 42a disposed directly above the undersurface 1b of the workpiece 1, receiving the reflected ultrasonic wave or the like by the measuring unit 42a, and analyzing the ultrasonic wave or the like. Hence, the measuring unit 42a is a noncontact-type sensor.

The noncontact-type second thickness measuring instrument 42 includes, for example, a rotatable shaft portion 42b erected from the upper surface of the base 4 of the grinding apparatus 2 and an arm portion 42c extending in the horizontal direction from an upper end of the shaft portion 42b. The measuring unit 42a is fixed to a distal end of the arm portion 42c. A lower end of the shaft portion 42b is connected with an unillustrated rotating mechanism which is formed by a piston, a motor, or the like. The rotating mechanism rotates the shaft portion 42b. When the shaft portion 42b is rotated, the measuring unit 42a moves in an arcuate measurement track about the shaft portion 42b. That is, the grinding apparatus 2 includes a measuring unit moving mechanism that reciprocates the measuring unit 42a in the measurement track above the workpiece 1 held on the chuck table 8. While the second grinding unit 10b grinds the undersurface 1b of the workpiece 1, the measuring unit 42a can be moved above the undersurface 1b and measure the thickness of different positions of the undersurface 1b of the workpiece 1.

However, the measuring unit 42a cannot enter a position that interferes with the second grinding unit 10b grinding the workpiece 1. While the workpiece 1 is ground, the second grinding stones 20b are continuously in contact with a central portion of the workpiece 1 at all times, and hence, there is no timing for the measuring unit 42a to enter a position above the central portion of the workpiece 1. That is, the measuring unit moving mechanism reciprocates the measuring unit 42a in the measurement track between a position above the outer circumference of the workpiece 1 held on the chuck table 8 and a position above the workpiece 1 which does not interfere with the grinding unit 10a or 10b.

The grinding apparatus 2 further includes a controller (control unit) 90 that controls various constituent elements. The controller 90 controls, for example, the turntable 6, the chuck table 8, the grinding units 10a and 10b, the wafer transfer robot 30, the positioning table 32, the loading arm 34, the unloading arm 36, the spinner cleaning apparatus 38, and the like. The controller 90 is constituted by, for example, a computer including a processing apparatus such as a central processing unit (CPU) or a microprocessor and a storage apparatus such as a flash memory or a hard disk drive. Further, the controller 90 makes the processing apparatus operate according to software such as a program stored in the storage apparatus, and thereby functions as concrete means in which the software and the processing apparatus (hardware resources) cooperate with each other. The controller 90 stores, in the storage apparatus, processing conditions for grinding various kinds of workpieces 1 in the grinding units 10a and 10b, various kinds of information, and the like. The processing conditions stored in the storage apparatus include such information as the kinds and sizes of the workpieces 1 to be processed, finished thicknesses in the rough grinding and the finish grinding, and rotational speeds of the spindles 14a and 14b.

For example, the controller 90 has a grinding control section 92 that makes the grinding of the workpiece 1 performed by controlling various constituent elements. When the workpiece 1 is to be ground, the grinding control section 92 rotates the chuck table 8 holding the workpiece 1 about the table rotational axis 58, and rotates the grinding wheel 18a or 18b of the grinding unit 10a or 10b about the spindle 14a or 14b. Then, the spindle 14a or 14b is lowered by the raising and lowering mechanism 24a or 24b to be brought close to the chuck table 8, the grinding stones 20a or 20b are brought into contact with the workpiece 1 held on the chuck table 8, and the workpiece 1 is ground. The grinding control section 92 controls various constituent elements according to grinding conditions stored in the controller 90. The grinding control section 92 monitors the thickness of the workpiece 1 by the thickness measuring instrument 40 or 42 while making the grinding of the workpiece 1 progress. When the workpiece 1 is reduced to a predetermined thickness, the grinding control section 92 stops the lowering of the spindle 14a or 14b and stops the grinding of the workpiece 1.

Here, as illustrated in FIG. 2 and the like, the holding surface 8a of the chuck table 8 is constituted by a very gentle circular conical surface having the center of the holding surface 8a as a vertex thereof. When the holding surface 8a is the circular conical surface and the chuck table 8 holds under suction the workpiece 1, the workpiece 1 is slightly deformed in such a manner as to follow the holding surface 8a. Incidentally, characteristics of the shapes of the workpiece 1, the chuck table 8, and the like depicted in the figures are exaggerated for the convenience of description. The description will be continued by taking as an example the finish grinding performed by the second grinding unit 10b illustrated in FIG. 2.

When the workpiece 1 is ground, the chuck table 8 is rotated about the table rotational axis 58 in this state, and the second spindle 14b is lowered while being rotated, so that the second grinding stones 20b are brought into contact with the undersurface 1b of the workpiece 1. Then, the workpiece 1 placed on the chuck table 8 rotates while grinding processing progresses in an arcuate region from the center to the outer circumference of the workpiece 1. An entire region of the workpiece 1 is thereby ground. The inclination of the table rotational axis 58 is adjusted such that the top surface 1a and the undersurface 1b of the ground workpiece 1 are parallel with each other, that is, such that, among generatrices constituting the holding surface 8a formed by the circular conical surface, a generatrix closest to a rotational plane including the annular track of the second grinding stones 20b is parallel with the rotational plane. Then, the second thickness measuring instrument 42 monitors the thickness of the workpiece 1. When the workpiece 1 is reduced to a predetermined thickness, the lowering of the second spindle 14b by the raising and lowering mechanism 24b is stopped, and the grinding of the workpiece 1 is ended.

Incidentally, when a relative inclination between the table rotational axis 58 and the second spindle 14b is not appropriate, the thickness distribution of the workpiece 1 is not uniform, and a deviation occurs in thickness thereof, so that the top surface 1a and the undersurface 1b of the workpiece 1 after being ground are not parallel with each other. In view of this, while the workpiece 1 is ground, the measuring unit 42a of the second thickness measuring instrument 42 is moved to measure the thickness of different positions of the workpiece 1. Then, the thickness distribution of the workpiece 1 is monitored. When a problem has occurred in the thickness distribution, the inclination of the table rotational axis 58 or the like may be adjusted by the inclination adjusting unit. For example, the controller 90 has a necessary adjustment amount calculating section 94. The necessary adjustment amount calculating section 94 obtains the thickness information of the workpiece 1 being ground by the grinding unit 10a or 10b, by using the thickness measuring instrument 42, and calculates an adjustment amount necessary for inclination adjustment to be made by the inclination adjusting unit, as a necessary adjustment amount, in reference to the thickness information.

Incidentally, the thickness information of the workpiece 1 obtained by the necessary adjustment amount calculating section 94 by using the thickness measuring instrument 42 is, for example, a set of thickness values of different positions of the workpiece 1. When the workpiece 1 is ground by the grinding unit 10a or 10b, the thickness of the workpiece 1 is similar at points equal to each other in distance from the center of the workpiece 1. Accordingly, the thickness information of the workpiece 1 may be represented by a relation between the distance from the center of the workpiece 1 and the thickness of the workpiece 1 at the position separated from the center of the workpiece 1 by the distance. A further example of a configuration of the thickness information of the workpiece 1 will next be described in detail.

Here, a detailed description will be made of a relation between a deviation in the thickness distribution of the workpiece 1 in a grinding process and the inclination of the table rotational axis 58. In the following, a description will be made by taking as an example a situation in which the second grinding unit 10b finish-grinds the workpiece 1. However, this relation applies also to a case where the first grinding unit 10a roughly grinds the workpiece.

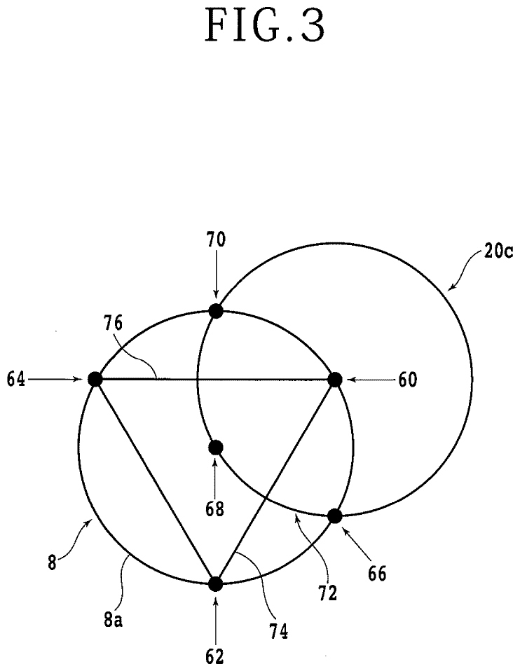

FIG. 3 is a plan view schematically illustrating a planar positional relation between the holding surface 8a of the chuck table 8 and the annular track 20c in which the second grinding stones 20b move. In FIG. 3, the contour of the holding surface 8a of the chuck table 8 which is in the shape of a circular conical surface and the annular track 20c are schematically illustrated in a circular shape. The diameter of the circular annular track 20c is similar to the diameter of the holding surface 8a of the chuck table 8. Further, the table rotational axis 58 of the chuck table 8 penetrates a center 68 of the holding surface 8a.

In addition, FIG. 3 illustrates the positions of the fixed shaft 60 and the two adjusting shafts 62 and 64, which support the chuck table 8 from below. The fixed shaft 60 is located below a substantially center of the second grinding wheel 18b. The fixed shaft 60 and the two adjusting shafts 62 and 64 are each arranged in such a manner as to constitute a vertex of a regular triangle. The chuck table 8 is supported by the fixed shaft 60 and the adjusting shafts 62 and 64. The adjusting shafts 62 and 64 function as the inclination adjusting unit. For example, when the adjusting shaft 64 is extended or contracted without the adjusting shaft 62 being extended or contracted, the chuck table 8 is changed in inclination in such a manner as to rotate about a first axis 74 connecting the fixed shaft 60 and the adjusting shaft 62 to each other. In addition, when the adjusting shaft 62 is extended or contracted without the adjusting shaft 64 being extended or contracted, the chuck table 8 is changed in inclination in such a manner as to rotate about a second axis 76 connecting the fixed shaft 60 and the adjusting shaft 64 to each other. That is, the inclination of the table rotational axis 58 can be changed by extending or contracting the adjusting shaft 62 and the adjusting shaft 64.

When the workpiece 1 is ground, the inclination of the table rotational axis 58 is adjusted by the inclination adjusting unit such that a generatrix connecting the center 68 and an outer circumferential position 66 of the holding surface 8a coinciding with the annular track 20c is parallel with the annular track 20c. Further, the second grinding stones 20b moving along the annular track 20c come into contact with the undersurface 1b of the workpiece 1 in a grinding region 72 between an upper side of the center 68 of the holding surface 8a and an upper side of the outer circumferential position 66, and grind the workpiece 1. Incidentally, the second grinding stones 20b do not come into contact with the workpiece 1 in a region between an upper side of the center 68 of the holding surface 8a and an upper side of another outer circumferential position 70.

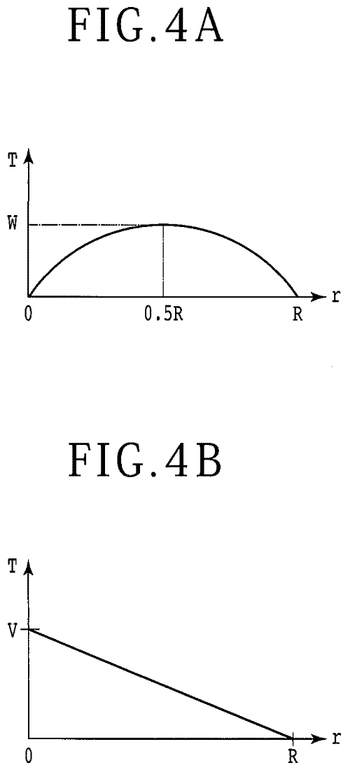

FIG. 4A and FIG. 4B are graphs of assistance in explaining a thickness distribution appearing in the workpiece 1 as a result of grinding performed on the workpiece 1 when the relative inclination between the table rotational axis 58 and the second spindle 14b is inappropriate. In each of the graphs, an axis of abscissas indicates a distance from the center of the workpiece 1, and an axis of ordinates indicates the magnitude of deviation in the thickness of the workpiece 1. When the workpiece 1 is ground, the chuck table 8 is rotated about the table rotational axis 58, and the second grinding wheel 18b is rotated about the second spindle 14b. At this time, a circular region separated from the center of the workpiece 1 by a desired distance is similarly ground, and hence, the thickness distribution of the workpiece 1 is substantially uniform in this circular region. Therefore, as illustrated in the graphs of FIG. 4A and FIG. 4B, the thickness distribution of the workpiece 1 can be evaluated according to a relation between the distance from the center of the workpiece 1 and an amount of deviation in the thickness of the workpiece 1.

The thickness distribution illustrated in the graph of FIG. 4B is an example of the thickness distribution that appears in the workpiece 1 in a case where an inclination occurs over the whole of the grinding region 72 between the center and the outer circumference of the workpiece 1. This thickness distribution is a thickness distribution that appears in the workpiece 1 in a case where the annular track 20c of the second grinding stones 20b and the generatrix connecting the center 68 and the outer circumferential position 66 of the holding surface 8a to each other are not parallel with each other. More specifically, the thickness distribution illustrated in the graph of FIG. 4B is a thickness distribution in a case where a distance between the holding surface 8a and the annular track 20c is larger at the center 68 of the holding surface 8a than at the outer circumferential position 66 of the holding surface 8a. Further, a difference between the thickness at the center of the workpiece 1 and the thickness at the outer circumference of the workpiece 1 is illustrated as a thickness deviation V in FIG. 4B. Incidentally, the deviation V is a negative value when the distance between the holding surface 8a and the annular track 20c is larger at the outer circumferential position 66 than at the center 68 of the holding surface 8a.

Incidentally, in connection with a sectional shape that appears in the workpiece 1 due to the deviation V, this deviation V can also be referred to as a “protruding amount” or a “V amount.” In order to resolve the deviation in the thickness distribution illustrated in the graph of FIG. 4B, it suffices to adjust mainly the length of the adjusting shaft 64 such that the holding surface 8a and the annular track 20c become parallel with each other. As illustrated in FIG. 4B, the deviation in the thickness can be expressed by a linear function of the distance from the center of the workpiece 1 (axis of abscissas) and the amount of deviation in the thickness of the workpiece 1 (axis of ordinates). This linear function yields V on the axis of ordinates in a case of zero on the axis of abscissas, and yields zero on the axis of ordinates in a case of R as the value of the radius of the workpiece 1 on the axis of abscissas.

In addition, the thickness distribution illustrated in the graph of FIG. 4A is an example of the thickness distribution that appears in the workpiece 1 in a case where a grinding depth of the second grinding stones 20b is shallow or deep in a central portion of the grinding region 72 between the center and the outer circumference of the workpiece 1. In order to resolve the deviation in the thickness distribution illustrated in FIG. 4A, it is preferable to, while adjusting mainly the adjusting shaft 62, extend or contract the adjusting shaft 64 in such a manner as to accommodate a change in inclination over the whole of the grinding region 72 which is caused by the adjustment of the adjusting shaft 62. More specifically, the thickness distribution illustrated in the graph of FIG. 4A is a thickness distribution in a case where the grinding depth of the second grinding stones 20b is shallow in the central portion of the grinding region 72 between the center and the outer circumference of the workpiece 1. Further, a difference between the thickness in the central portion of the grinding region 72 of the workpiece 1 and the thickness at the center and the outer circumference of the workpiece 1 is illustrated as a thickness deviation W in FIG. 4A. W is a negative value when the central portion of the grinding region 72 of the workpiece 1 is ground deeper than surroundings.

Incidentally, in connection with a sectional shape that appears in the workpiece 1 due to the deviation W, this deviation W can also be referred to as a “gull amount” or a “W amount.” The adjustment amounts of the adjusting shafts 62 and 64 are preferably determined such that the deviation W becomes zero. As illustrated in FIG. 4A, this deviation W in the thickness can be expressed by a quadratic function of the distance from the center of the workpiece 1 (axis of abscissas) and the amount of deviation in the thickness of the workpiece 1 (axis of ordinates). This quadratic function yields zero on the axis of ordinates in a case of zero on the axis of abscissas, yields W on the axis of ordinates in a case of 0.5 R on the axis of abscissas, and yields zero on the axis of ordinates in a case of R on the axis of abscissas.

The thickness information of the workpiece 1 obtained by use of the thickness measuring instrument 40 or 42 may be constituted by the V amount and the W amount. Incidentally, when the lengths of the adjusting shafts 62 and 64 are both appropriate, that is, when the relative inclination between the table rotational axis 58 and the spindle 14a or 14b is appropriate, the thickness of the workpiece 1 is the same over the entire region, and the V amount and the W amount are zero. In addition, when the relative inclination between the table rotational axis 58 and the spindle 14a or 14b is inappropriate, a thickness distribution resulting from addition of the thickness distribution represented in the graph illustrated in FIG. 4A and the thickness distribution represented in the graph illustrated in FIG. 4B appears in the workpiece 1. Conversely, the thickness distribution that appears in the workpiece 1 when the relative inclination between the table rotational axis 58 and the spindle 14a or 14b is inappropriate can be separated into the thickness distribution represented by the graph illustrated in FIG. 4A and the thickness distribution represented by the graph illustrated in FIG. 4B.

The controller 90 calculates the adjustment amount such that the deviation W becomes zero in the graph illustrated in FIG. 4A and such that the deviation V becomes zero in the graph illustrated in FIG. 4B. Then, the inclination adjusting unit adjusts the relative inclination between the table rotational axis 58 and the spindle 14a or 14b. In other words, the controller 90 has the necessary adjustment amount calculating section 94. The necessary adjustment amount calculating section 94 obtains, by using the thickness measuring instrument 40 or 42, the thickness information of the workpiece 1 (for example, the thickness distribution at different positions of the workpiece 1 or the sectional shape of the workpiece 1) being ground by the grinding unit 10a or 10b. Then, an adjustment amount necessary for inclination adjustment to be made by the inclination adjusting unit is calculated as a necessary adjustment amount in reference to the thickness information. The controller 90 carries out the grinding of the workpiece 1 by the grinding control section 92 while adjusting the relative inclination between the table rotational axis 58 and the spindle 14a or 14b in reference to the calculated necessary adjustment amount.

However, it takes some time for an effect of the adjustment of the inclination of the table rotational axis 58 or the like to be reflected in the thickness distribution of the workpiece 1 after the adjustment is made. That is, the thickness distribution of the workpiece 1 is not significantly corrected at a time point at which the adjustment of the inclination of the table rotational axis 58 or the like is completed. The thickness distribution of the workpiece 1 is optimized when the grinding of the workpiece 1 thereafter progresses to a certain extent and the grinding of a part having a larger thickness than expected in the workpiece 1 progresses more significantly than in surroundings. That is, the optimization of the thickness distribution of the workpiece 1 takes some time. Therefore, a control method in feedback control of an ordinary actuator or the like cannot be simply applied to grinding progress management in the grinding apparatus 2. It can be explained that this is because a relation between a target of correction and a target of progress management is different between the grinding progress management and the feedback control of a driving source.

In grinding, the inclination of the table rotational axis 58 or the like as the target of operation correction is not directly related to the thickness distribution of the workpiece 1 as the target of progress management. That is, the inclination adjusting unit in the grinding apparatus 2 adjusts the inclination of the table rotational axis 58 or the like, but not the shape of the workpiece 1. In contrast, in a case of an ordinary actuator or the like, when an operation mode of the driving source such as a motor is changed, a movement mode of a movable part changes immediately. That is, the operation of the driving source as the target of operation correction in feedback control directly affects the movement mode of the movable part as the target of progress management. Therefore, the control method for the actuator or the like cannot be simply applied to the grinding progress management in the grinding apparatus 2.

For example, the inclination of the table rotational axis 58 or the like may be readjusted in a transient period in which, after the inclination of the table rotational axis 58 or the like is adjusted by actuating the inclination adjusting unit during the progress of grinding of the workpiece 1, an effect of the adjustment is reflected in the thickness distribution of the workpiece 1. In this case, the already adjusted inclination of the table rotational axis 58 or the like is further changed, and the adjustment amount tends to be excessive. As a result, the thickness distribution of the workpiece 1 is not likely to be as planned. In addition, excessive adjustment and excessive correction for the excessive adjustment are repeated. As a result, a rapid decrease and a slow decrease in the thickness of the workpiece 1 being ground are repeated. A stable processing result is difficult to obtain when the processing conditions and a processing process are thus unstable. Meanwhile, in a case where a wait is performed for the next adjustment each time until the effect of the adjustment is reflected in the thickness distribution of the workpiece 1, the number of adjustments that can be made during the grinding of the workpiece 1 is decreased. Therefore, adjustment corresponding to processing conditions changing momently cannot be made, so that variations in the processing result are increased.

Incidentally, a method referred to as Proportional-Integral-Differential (PID) control or controller is known as a method of feedback control of an actuator or the like. The method refers to a method of making adjustment of an input value by three elements of a proportional term (Proportional), an integrating term (Integral), and a differentiating term (Derivative) for a deviation between an output value and a target value.

Basic feedback control performed with only the term proportional to the deviation among these terms is referred to as Proportional (P) control. The P control adjusts the input value by increasing an adjustment amount when the deviation is large and by decreasing the adjustment amount when the deviation is small. Feedback control performed with the term proportional to the deviation and an integrating term is referred to as PI control. The integrating term plays a role in making the value close to the target value by, when a state of deviation is continued for a long time, correspondingly increasing a change in the input value. However, this has an effect of delaying the control, and tends to make the output value unstable. Moreover, the term proportional to differential of the deviation performs a role of smoothly guiding the output value to the target value by suppressing oscillatory behavior of the output value. Control combining such a proportional operation, such an integrating operation, and such a differentiating operation is referred to as PID control.

The PID control and the P control described above may be applied as a control method for an actuator or the like to the grinding progress management in the grinding apparatus 2. For example, the necessary adjustment amount calculating section 94 of the controller 90 calculates the necessary adjustment amount to perform the PID control of the inclination in reference to the thickness information of the workpiece 1 obtained by the thickness measuring instrument 40 or 42. Alternatively, the necessary adjustment amount calculating section 94 of the controller 90 calculates the necessary adjustment amount to perform the P control of the inclination in reference to the thickness information of the workpiece 1 obtained by the thickness measuring instrument 40 or 42. However, the PID control or the P control alone does not constitute control that can deal with a shape change caused by a change in processing conditions (a change in inclination at a processing point due to a change in a processing load, an effect of a thermal expansion of a member, and the like) in the grinding apparatus 2. As will be described later in detail, it has been confirmed that simply applying these control methods to the grinding progress management in the grinding apparatus 2 results in variations in a finished shape of the workpiece 1.

A description has thus far been made of a fact that, when the relative inclination between the table rotational axis 58 and the spindle 14a or 14b is adjusted with the controller 90 of the grinding apparatus 2 using the control method for an actuator or the like or not using the control method, the adjustment cannot completely be made simply by the calculated necessary adjustment amount. Accordingly, in the grinding apparatus 2 according to the present embodiment, the controller 90 calculates an actual adjustment amount by multiplying the necessary adjustment amount calculated by the necessary adjustment amount calculating section 94 by a predetermined adjustment rate, and adjusts the inclination by the actual adjustment amount. In other words, the controller 90 of the grinding apparatus 2 according to the present embodiment further includes an actual adjustment amount calculating section 96 that calculates the actual adjustment amount by multiplying the necessary adjustment amount calculated by the necessary adjustment amount calculating section 94 by the adjustment rate and an adjustment control section 98 that adjusts the inclination by the actual adjustment amount. The adjustment control section 98 appropriately adjusts the inclination by the actual adjustment amount calculated by the actual adjustment amount calculating section 96, by controlling the inclination adjusting unit. In this adjustment, the adjustment is made with consideration given to circumstances specific to the grinding of the workpiece 1 in the grinding apparatus 2.

Here, a description will be made of a relation between the adjustment rate by which the necessary adjustment amount is multiplied when the actual adjustment amount calculating section 96 calculates the actual adjustment amount and changes in the thickness of the workpiece 1 ground by the grinding unit 10a or 10b. In particular, a description will be made based on an experiment in which the V amount described with reference to FIG. 4B was obtained as the thickness information of the workpiece 1, the necessary adjustment amount was calculated from the V amount, the actual adjustment amount was calculated by multiplying the necessary adjustment amount by various adjustment rates, and the inclination of the spindle 14a or 14b was adjusted.

The experiment in which the workpiece 1 was ground while the inclination of the spindle 14a or 14b was adjusted was performed as described as follows. First, a plurality of Si wafers having a diameter of 12 inches were prepared as the workpiece 1, and a grinding wheel 18a or 18b suitable for the grinding of the Si wafers was fitted to the lower end of the spindle 14a or 14b. Next, one workpiece 1 was placed on the holding surface 8a of the chuck table 8, and the workpiece 1 was held under suction by the chuck table 8. The chuck table 8 was thereafter moved to a predetermined position below the grinding wheel 18a or 18b. Then, the rotation of the spindle 14a or 14b was started and set to a rotational speed of 3400 rpm, the rotation of the chuck table 8 was started and set to a rotational speed of 300 rpm, and the lowering of the grinding wheel 18a or 18b was started. While the workpiece 1 was ground and thinned by contact of the grinding stones 20a or 20b with the upper surface (undersurface 1b) of the workpiece 1, the thickness measuring instrument 40 or 42 monitored the thickness of the workpiece 1, and the V amount was obtained as the thickness information of the workpiece 1.

At this time, while the obtained V amount was referred to, the necessary adjustment amount for adjusting the inclination of the spindle 14a or 14b to perform the P control on the V amount was repeatedly calculated such that the V amount ultimately became zero. Then, each time the necessary adjustment amount was calculated, the actual adjustment amount was calculated by multiplying the necessary adjustment amount by the predetermined adjustment rate, and the inclination of the spindle 14a or 14b was adjusted by the actual adjustment amount. In this way, changes in the V amount were observed while the grinding of the workpiece 1 was made to progress. Here, in the experiment performed on each of the plurality of workpieces 1, mutually different values were set as the adjustment rate when the actual adjustment amount was calculated. More specifically, letting Δy (t) be the necessary adjustment amount for performing the adjustment by the P control, an adjustment rate Kp by which Ay (t) is to be multiplied was set at 0, 0.2, 0.3, 0.4, 0.5, or 1.0, the actual adjustment amount was calculated according to each of the adjustment rates, and the inclination of the spindle 14a or 14b was adjusted by the actual adjustment amount.

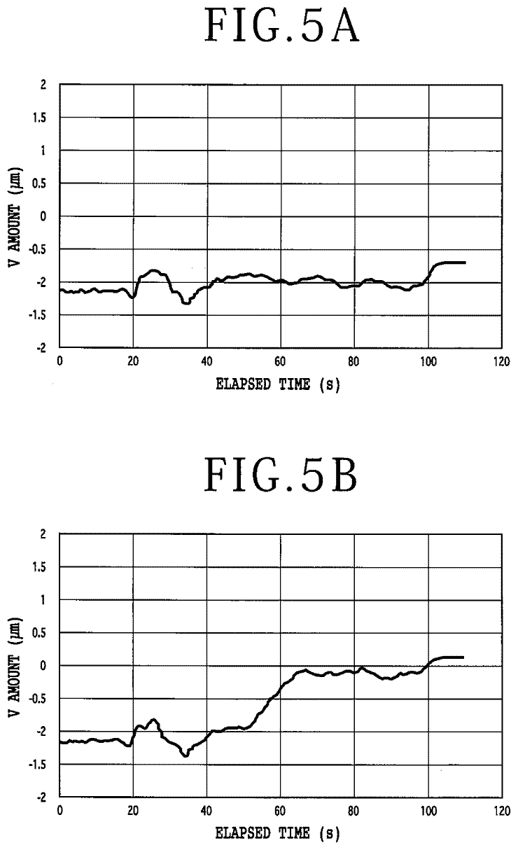

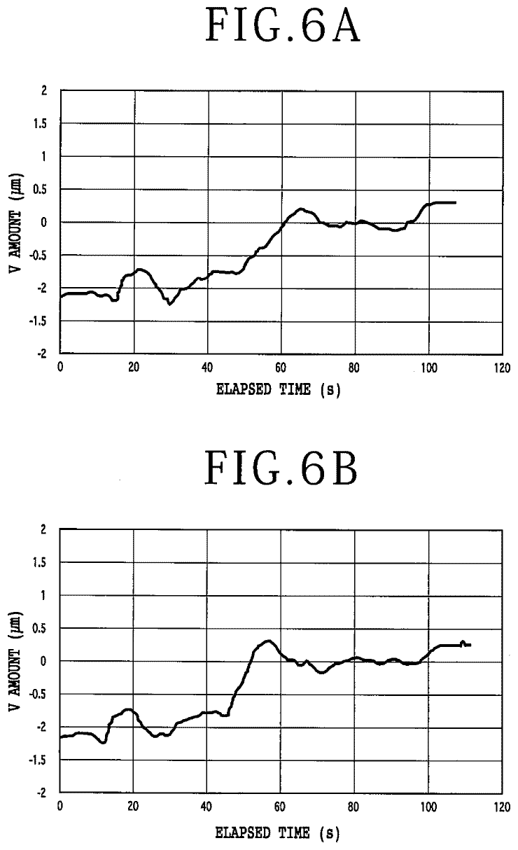

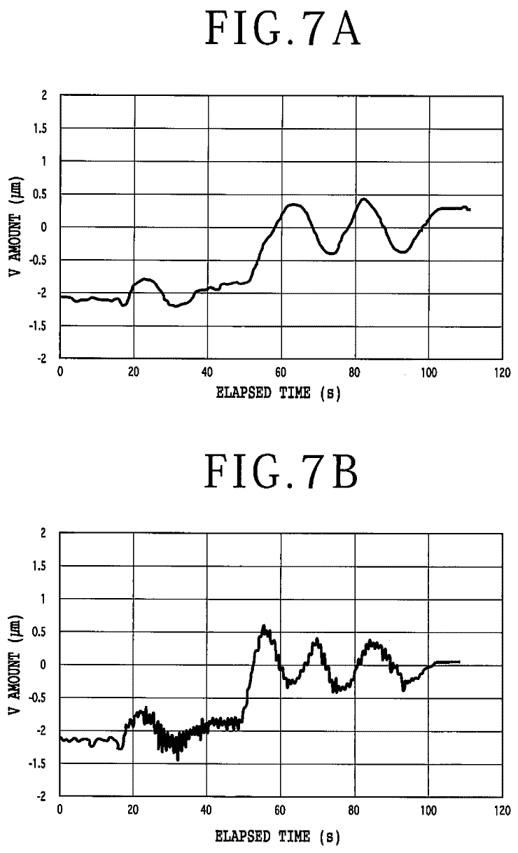

A result of the experiment will be described. FIG. 5A is a graph illustrating changes in the V amount in a case where the adjustment rate Kp was set at 0.0. FIG. 5B is a graph illustrating changes in the V amount in a case where the adjustment rate Kp was set at 0.2. FIG. 6A is a graph illustrating changes in the V amount in a case where the adjustment rate Kp was set at 0.3. FIG. 6B is a graph illustrating changes in the V amount in a case where the adjustment rate Kp was set at 0.4. FIG. 7A is a graph illustrating changes in the V amount when the adjustment rate Kp was set at 0.5. FIG. 7B is a graph illustrating changes in the V amount in a case where the adjustment rate Kp was set at 1.0. In each graph, the grinding stones 20a or 20b came into contact with the workpiece 1 approximately when an elapsed time became 20 seconds (20 s), the thickness information of the workpiece 1 was obtained at the same time as a start of the grinding of the workpiece 1, and adjustment of the inclination of the spindle 14a or 14b or the like was started. Further, approximately when the elapsed time became 100 s, the lowering of the grinding wheel 18a or 18b was stopped, and the grinding of the workpiece 1 was ended.

In the following, each graph will be evaluated individually. First, in the case where the adjustment rate Kp was set at 0.0, that is, in a case where the actual adjustment amount was zero and thus substantially no adjustment was made, a state in which the V amount deviated from zero to a certain degree was maintained, as illustrated in FIG. 5A. It is understood from this result that the workpiece 1 in a predetermined shape is not obtained when the inclination of the spindle 14a or 14b or the like is not adjusted.

Next, in the case where the adjustment rate Kp was set at 1.0, that is, in a case where adjustment was performed simply by the P control with the necessary adjustment amount set as the actual adjustment amount without any change, a state in which the V amount oscillated on opposite sides of zero was observed, as illustrated in FIG. 7B. The oscillation of the V amount means that repetition of adjustment of the inclination of the spindle 14a or 14b and correction of the adjustment occurs. In the experiment result illustrated in FIG. 7B, the lowering of the grinding wheel 18a or 18b is ended and the grinding of the workpiece 1 is ended when the V amount approaches zero. However, this can be said to occur by chance. Depending on conditions of the progress of the grinding, the grinding may be ended when the V amount greatly deviates from zero.

That is, it is understood from this result that, in the case where the inclination of the spindle 14a or 14b is adjusted by the P control alone, oscillation of the V amount is observed, and the V amount at a time point of the ending of the grinding is not likely to be constant. In other words, it is understood that a stable grinding result is not obtained by the P control alone. The same is considered to apply to a case where the PID control is performed in place of the P control. In this regard, also in the case where the adjustment rate Kp was set at 0.5, oscillation of the V amount was similarly observed, as illustrated in FIG. 7A. However, as compared with the case where Kp was set at 1.0, the cycle of the oscillation was lengthened in the case where Kp was 0.5. Hence, it is understood that a state of the oscillation of the V amount changes according to Kp.

Moreover, it was confirmed that, in the case where the adjustment rate Kp was set at 0.4, as illustrated in FIG. 6B, substantially no oscillation of the V amount was observed, and the V amount converged to a value close to zero. In addition, it was similarly confirmed that, in the case where the adjustment rate Kp was set at 0.3, as illustrated in FIG. 6A, the V amount converged to a value close to zero. As illustrated in FIG. 5B, a similar tendency was confirmed also in the case where the adjustment rate Kp was set at 0.2. Hence, it is understood that, under an environment under which this experiment was performed, an excellent grinding result is obtained when the actual adjustment amount is calculated with the adjustment rate Kp set at equal to or more than 0.2 but equal to or less than 0.4, and the inclination of the spindle 14a or 14b is adjusted by the calculated actual adjustment amount. However, in the case where Kp was 0.4, as illustrated in FIG. 6B, a relatively large overshoot of the V amount was observed before an elapsed time of 60 s. Meanwhile, it was confirmed that, in the case where Kp was 0.2, as illustrated in FIG. 5B, the elapsed time taken for the V amount to approach zero was relatively long, and the V amount converged in a state of being lower than zero. It is therefore understood that an adjustment rate Kp of 0.3 is most preferable.

It has been confirmed by the above experiment that an excellent grinding result is obtained by obtaining the thickness information of the workpiece 1, calculating the necessary adjustment amount in reference to the thickness information, calculating the actual adjustment amount by multiplying the necessary adjustment amount by the predetermined adjustment rate Kp, and adjusting the inclination of the spindle 14a or 14b or the like. Moreover, it is understood that, when the grinding of the workpiece 1 is performed under the processing conditions similar to those of the experiment described above, an excellent grinding result is obtained by setting the adjustment rate Kp at equal to or more than 0.2 but equal to or less than 0.4. That is, when the actual adjustment amount is calculated by multiplying the necessary adjustment amount by the predetermined adjustment rate Kp and the inclination is adjusted by the actual adjustment amount, the inclination is adjusted at a moderate speed, and repetition of adjustment and correction of the adjustment does not occur. It is thus possible to reduce variations in the processing result and the like that accompany the adjustment of the inclination. Hence, the grinding apparatus 2 according to the present embodiment can accurately and uniformly grind the workpiece 1 to a predetermined thickness by moderately adjusting the processing conditions while grinding the workpiece 1.

Incidentally, in a case where the grinding is to be performed in the grinding apparatus 2 under new grinding conditions, an adjustment rate at which the processing result is stable in an excellent state is preferably derived by performing, in advance, an experiment of grinding the workpiece 1 while changing the adjustment rate. In this case, an excellent processing result is obtained stably by performing the grinding while using the derived adjustment rate. However, the adjustment rate used when the workpiece 1 is ground does not need to be derived by an empirical method. When conditions for the grinding to be performed by the grinding apparatus 2 are input to the controller 90 of the grinding apparatus 2, the controller 90 may read the adjustment rate used at a time of the grinding performed by the grinding apparatus 2 under similar conditions in the past. In this case, an excellent processing result is obtained when the grinding is performed while the read adjustment rate is used.

Incidentally, the adjustment rate by which the necessary adjustment amount is multiplied to calculate the actual adjustment amount does not need to be determined in advance. Each time the grinding of the workpiece 1 is performed, the actual adjustment amount calculating section 96 may calculate the adjustment rate based on a predetermined condition, and calculate the actual adjustment amount by using the calculated adjustment rate. In this case, for example, the actual adjustment amount calculating section 96 may determine the adjustment rate in reference to the thickness information of the workpiece 1 obtained by the thickness measuring instrument 40 or 42 or the necessary adjustment amount calculated by the necessary adjustment amount calculating section 94.

For example, when the shape of the workpiece 1 indicated by the thickness information greatly deviates from an ideal state and the necessary adjustment amount calculated by the necessary adjustment amount calculating section 94 is relatively large, the relative inclination between the table rotational axis 58 and the spindle 14a or 14b is adjusted greatly by increasing the adjustment rate. In this case, it is possible to avoid a situation in which sufficient adjustment is not performed because the adjustment is not performed in time before the grinding is ended. Meanwhile, for example, when the shape of the workpiece 1 indicated by the thickness information slightly deviates from the ideal state and the necessary adjustment amount calculated by the necessary adjustment amount calculating section 94 is relatively small, the relative inclination between the table rotational axis 58 and the spindle 14a or 14b is finely adjusted by decreasing the adjustment rate. In this case, it is possible to avoid a situation in which adjustment and excessive correction for the excessive adjustment are repeated. A stable processing result is likely to be consequently obtained.

Further, the adjustment rate used by the actual adjustment amount calculating section 96 while the grinding of the workpiece 1 is performed does not need to be one value. That is, the adjustment rate used by the actual adjustment amount calculating section 96 may change while the grinding of one workpiece 1 progresses. For example, the actual adjustment amount calculating section 96 adjusts the inclination by a relatively high adjustment rate while the shape of the workpiece 1 indicated by the thickness information greatly deviates from the ideal state, that is, while the necessary adjustment amount is calculated to be high. On the other hand, the actual adjustment amount calculating section 96 adjusts the inclination by a relatively low adjustment rate when the shape of the workpiece 1 indicated by the thickness information deviates slightly from the ideal state, that is, when the necessary adjustment amount is calculated to be low. The actual adjustment amount calculating section 96 may thus change the adjustment rate. Here, a value indicated by the thickness information of the workpiece 1 as a condition for changing the adjustment rate or a threshold value of the necessary adjustment amount will be referred to as a selection threshold value. For example, the actual adjustment amount calculating section 96 sets the adjustment rate to a first adjustment rate when the value indicated by the thickness information or the necessary adjustment amount calculated by the necessary adjustment amount calculating section 94 is higher than the selection threshold value. In addition, the actual adjustment amount calculating section 96 sets the adjustment rate to a second adjustment rate lower than the first adjustment rate when the value indicated by the thickness information or the necessary adjustment amount is equal to or less than the selection threshold value.

Next, a description will be made of an experiment in which the adjustment rate by which the necessary adjustment amount is multiplied when the actual adjustment amount calculating section 96 calculates the actual adjustment amount is changed during progress of the grinding of the workpiece 1 and the inclination of the spindle 14a or 14b or the like is adjusted by the adjustment control section 98 in reference to the actual adjustment amount calculated. Also in the present experiment, as in the experiment described above, the V amount described with reference to FIG. 4B was obtained as the thickness information of the workpiece 1, and the adjustment rate was calculated from the V amount. Further, the inclination of the spindle 14a or 14b was adjusted such that the V amount approaches zero. Incidentally, in the present experiment, while three workpieces 1 were each ground, the adjustment rate was calculated by respective different methods. Here, conditions for the grinding of the workpieces 1 performed in the present experiment are similar to the conditions for the grinding performed in the experiment described above, and hence, a description of the conditions for the grinding in the present experiment will be omitted.

In the present experiment, letting Δy (t) be the necessary adjustment amount for making the adjustment by the P control, the adjustment rate Kp by which Ay (t) is to be multiplied was selected under the following conditions. First, the actual adjustment amount was calculated under conditions where the adjustment rate Kp was set at 0.5 when the absolute value of the V amount as a value indicated by the thickness information exceeded 0.5 μm and the adjustment rate Kp was set at 0.1 when the absolute value of the V amount was equal to or less than 0.5 μm, and the workpiece 1 was ground while the inclination of the spindle 14a or 14b was adjusted. This will be referred to as a first condition. In addition, the actual adjustment amount was calculated under conditions where the adjustment rate Kp was set at 0.3 when the absolute value of the V amount as a value indicated by the thickness information exceeded 0.5 μm and the adjustment rate Kp was set at 0.1 when the absolute value of the V amount was equal to or less than 0.5 μm, and the workpiece 1 was ground while the inclination of the spindle 14a or 14b was adjusted. This will be referred to as a second condition. That is, in the first condition and the second condition, the absolute value of 0.5 μm of the V amount as a value indicated by the thickness information is the selection threshold value. Further, for comparison, the actual adjustment amount was calculated with the adjustment rate set at 0.1 irrespective of the V amount, and the workpiece 1 was ground while the inclination of the spindle 14a or 14b was adjusted. This will be referred to as a comparative condition.

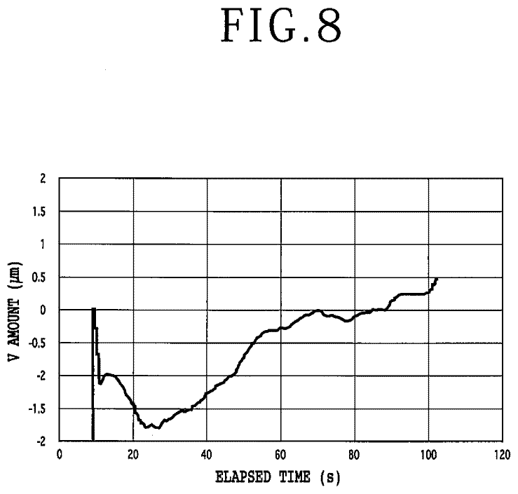

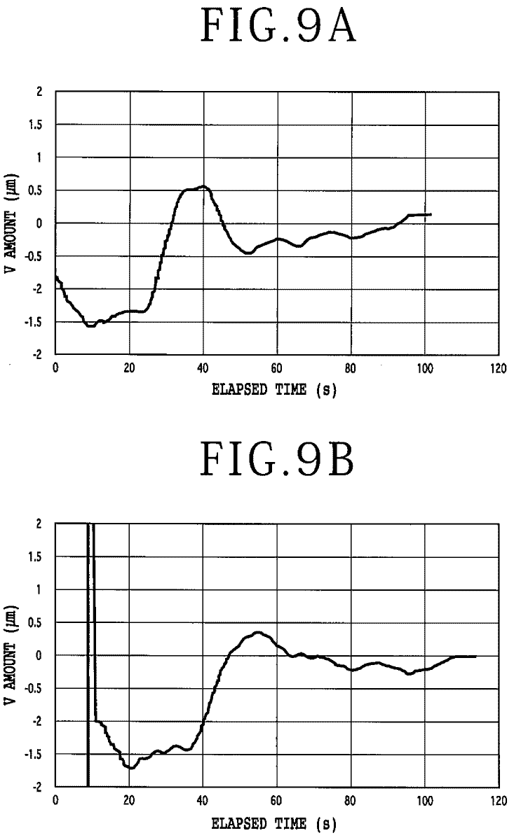

A result of the experiment will be described. FIG. 8 is a graph illustrating changes in the V amount in a case where the adjustment rate Kp was determined under the comparative condition. FIG. 9A is a graph illustrating changes in the V amount in a case where the adjustment rate Kp was determined under the first condition. FIG. 9B is a graph illustrating changes in the V amount in a case where the adjustment rate Kp was determined under the second condition. In each graph, the grinding stones 20a or 20b came into contact with the workpiece 1 when the elapsed time was 0 to 10 s, the thickness information of the workpiece 1 was obtained at the same time as a start of the grinding of the workpiece 1, and adjustment of the inclination of the spindle 14a or 14b was started. Further, when the elapsed time was 90 to 100 s, the lowering of the grinding wheel 18a or 18b was stopped, and the grinding of the workpiece 1 was ended.

In the following description, each graph will be evaluated individually. First, in a case where the adjustment rate Kp was set at 0.1 from a start to an end of the grinding, that is, in a case where the inclination of the spindle 14a or 14b was adjusted under the comparative condition, a state in which the V amount gradually approached zero was observed, as illustrated in FIG. 8. However, the progress of correction of the V amount was too slow.

Next, in a case where the inclination of the spindle 14a or 14b was adjusted under the first condition, the V amount changed as illustrated in FIG. 9A. First, there was observed a state in which the inclination of the spindle 14a or 14b was adjusted relatively quickly at an adjustment rate Kp of 0.5 and the V amount shifted to a negative approached zero rapidly during a period from an elapsed time of 20 s to an elapsed time of 40 s. However, there was also observed a state in which the V amount increased sharply and the V amount overshot without the sharp increase in the V amount being stopped even after the absolute value of the V amount became equal to or less than 0.5 μm and the adjustment rate Kp was thereby changed to 0.1.

In addition, in a case where the inclination of the spindle 14a or 14b was adjusted under the second condition, the V amount changed as illustrated in FIG. 9B. First, there was observed a state in which the inclination of the spindle 14a or 14b was adjusted at an adjustment rate Kp of 0.3 and the V amount shifted to a negative approached zero during a period from an elapsed time of 20 s to an elapsed time of 50 s. In the case where the inclination of the spindle 14a or 14b was adjusted under the second condition, the V amount increased more gently than in the adjustment under the first condition, and the correction of the V amount took relatively more time. Meanwhile, no overshoot of the V amount was observed after the absolute value of the V amount became equal to or less than 0.5 μm and the adjustment rate Kp was thereby changed to 0.1.

In each of the cases where the inclination of the spindle 14a or 14b was adjusted under the first condition and the second condition, the V amount was able to be made to greatly approach zero in a relatively short period of time. Meanwhile, the adjustment was able to be performed cautiously after the V amount approached zero. Thus, in a case of grinding the workpiece 1 while changing the adjustment rate Kp according to the V amount and adjusting the inclination of the spindle 14a or 14b or the like, the adjustment can be made swiftly and precisely, and an excellent processing result can stably be obtained. Here, the selection threshold value referred to when the adjustment rate Kp is changed is preferably set in such a manner as to enable the inclination of the spindle 14a or 14b or the like to be adjusted swiftly and precisely. That is, when the selection threshold value is too small, the inclination is adjusted at a high adjustment rate Kp even when the V amount decreases greatly, and hence, an overshoot tends to occur in an index related to the thickness of the workpiece 1 such as the V amount. When the selection threshold value is too large, on the other hand, the adjustment of the inclination is started at a low adjustment rate Kp from a state of a large V amount, and thus, the adjustment of the inclination takes a long time.

In addition, a description has thus far been made of cases where adjustment is made while the adjustment rate Kp is changed between a time when the V amount exceeds the selection threshold value and a time when the V amount is equal to or less than the selection threshold value. That is, a description has been made of cases where adjustment is made in two stages with the selection threshold value as a boundary. However, two or more selection threshold values may be used, and adjustment may be made in three stages or more.

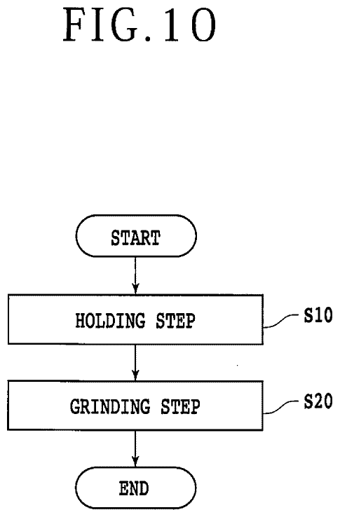

A method of grinding the workpiece 1 which is performed in the grinding apparatus 2 will next be described as a method of using the grinding apparatus 2 according to the present embodiment. The method of grinding the workpiece 1, which will be described in the following, is performed in the grinding apparatus 2 illustrated in FIG. 1, for example. FIG. 10 is a flowchart illustrating a flow of steps of the method of grinding the workpiece 1.

The method of grinding the workpiece 1 which is illustrated in FIG. 10 first performs a holding step S10 of holding the workpiece 1 by the chuck table 8 by placing the workpiece 1 on the holding surface 8a of the chuck table 8. The holding step S10 places the workpiece 1 on the holding surface 8a with the undersurface 1b as a grinding target surface of the workpiece 1 directed upward and with the top surface 1a directed to the holding surface 8a. Next, the suction source of the chuck table 8 is actuated to hold under suction the workpiece 1 on the chuck table 8. Thereafter, the chuck table 8 holding the workpiece 1 under suction is moved to a position below the grinding unit 10a or 10b. Preparation for the grinding of the workpiece 1 is thereby completed.

The method of grinding the workpiece 1 which is illustrated in FIG. 10 performs a grinding step S20 after the holding step S10. FIG. 2 is a sectional view schematically illustrating a manner in which the second grinding unit 10b grinds the workpiece 1. The grinding step S20 rotates the chuck table 8 about the table rotational axis 58, rotates the spindle 14a or 14b, and moves the chuck table 8 and the spindle 14a or 14b relative to each other in a direction of approaching each other. The grinding stones 20a or 20b are thereby brought into contact with the workpiece 1 to grind the workpiece 1. Here, the grinding step S20 obtains the thickness information of the workpiece 1 being ground by use of the thickness measuring instrument 40 or 42. Then, an adjustment amount necessary to adjust the inclination of one of or both the table rotational axis 58 and the spindle 14a or 14b is calculated as a necessary adjustment amount in reference to the obtained thickness information. In particular, the method of grinding the workpiece 1 which is illustrated in FIG. 10 calculates an actual adjustment amount by multiplying the necessary adjustment amount by an adjustment rate and adjusts the inclination by the actual adjustment amount.

Incidentally, in the grinding step S20, the necessary adjustment amount is preferably calculated such that the PID control of the inclination of the adjustment target can be performed in reference to the thickness information obtained regarding the workpiece 1. Alternatively, in the grinding step S20, the necessary adjustment amount is preferably calculated such that the P control of the inclination can be performed in reference to the thickness information. However, the method of calculating the necessary adjustment amount is not limited to the above. In addition, in the grinding step S20, the adjustment rate by which the necessary adjustment amount is to be multiplied is preferably determined in reference to the thickness information or the necessary adjustment amount. For example, in the grinding step S20, the adjustment rate may be set to the first adjustment rate when a value indicating the thickness information or the necessary adjustment amount is higher than the selection threshold value, and the adjustment rate may be set to the second adjustment rate lower than the first adjustment rate when the value is equal to or less than the selection threshold value.

As described thus far, the grinding apparatus 2 according to the present embodiment adjusts the inclination of one of or both the table rotational axis 58 and the spindle 14a or 14b while grinding the workpiece 1 by the grinding wheel 18a or 18b. More specifically, the thickness information of the workpiece 1 being ground is obtained, the adjustment amount necessary for adjustment of the inclination is calculated as the necessary adjustment amount in reference to the thickness information, and the actual adjustment amount is calculated by multiplying the necessary adjustment amount by the adjustment rate. Further, the inclination is adjusted by the actual adjustment amount. In this case, variations in the processing result and the like that accompany the adjustment of the inclination can be reduced by selecting a moderate adjustment rate such that the inclination can be adjusted at a moderate speed and such that repetition of adjustment and correction of the adjustment does not occur.

It is to be noted that the present invention is not limited to the description of the foregoing embodiment, and can be variously modified and carried out. For example, in the foregoing embodiment, a description has been made of a case where attention is directed to the V amount as the thickness information of the workpiece 1, the necessary adjustment amount is calculated such that the V amount becomes zero during the grinding of the workpiece 1, and the inclination of the table rotational axis 58 or the like is adjusted aimed at conditions where the V amount is zero. However, one aspect of the present invention is not limited to this. That is, the grinding apparatus 2 and the grinding method according to one aspect of the present invention may use the W amount described with reference to FIG. 4A, as the thickness information of the workpiece 1 which serves as an index for the adjustment, in place of the V amount. In this case, the necessary adjustment amount is preferably calculated aimed at a state in which the W amount is zero during the grinding of the workpiece 1. Further, the necessary adjustment amount may be calculated by referring to information that is the thickness information of the workpiece 1 but is different from the V amount and the W amount.

In addition, in the foregoing embodiment, results of experiments have been illustrated, and a description has been made mainly of a case where the adjustment rate by which the necessary adjustment amount is to be multiplied is determined while the V amount is referred to as the thickness information of the workpiece 1. However, one aspect of the present invention is not limited to this. That is, the grinding apparatus 2 and the grinding method according to one aspect of the present invention may determine the adjustment rate by which the necessary adjustment amount is to be multiplied while the W amount is referred to as the thickness information of the workpiece 1, in place of the V amount. Alternatively, the adjustment rate may be determined while an index different from the V amount and the W amount is referred to as the thickness information of the workpiece 1.

Further, the actual adjustment amount calculating section 96 of the grinding apparatus 2 according to one aspect of the present invention may determine the adjustment rate in reference to the necessary adjustment amount calculated by the necessary adjustment amount calculating section 94, in place of the thickness information of the workpiece 1. Further, the actual adjustment amount calculating section 96 may set the adjustment rate to the first adjustment rate when a value indicating the necessary adjustment amount in place of the thickness information is higher than the selection threshold value, and may set the adjustment rate to the second adjustment rate lower than the first adjustment rate when the value is equal to or less than the selection threshold value. That is, the selection threshold value may be set for the necessary adjustment amount rather than the thickness information.

The thickness information of the workpiece 1 during progress of the grinding indicates a deviation of the shape of the workpiece 1 from an ideal state in a case where the grinding progresses ideally. In addition, the necessary adjustment amount necessary for the inclination of the table rotational axis 58 or the like is an adjustment amount necessary to make the shape of the workpiece 1 the ideal state, and depends on the deviation of the shape of the workpiece 1 from the ideal state. That is, the adjustment amount is determined according to a mode of deviation of the shape of the workpiece 1 from the ideal state in both the case where the adjustment rate is determined in reference to the thickness information of the workpiece 1 and the case where the adjustment rate is determined in reference to the necessary adjustment amount. Hence, the inclination of the table rotational axis 58 or the like can be adjusted appropriately also in the case where the adjustment rate is determined in reference to the necessary adjustment amount calculated by the necessary adjustment amount calculating section 94 as in the case where the adjustment rate is determined in reference to the thickness information of the workpiece 1.

Incidentally, the workpiece 1 can be ground when the grinding apparatus 2 and the grinding method according to one aspect of the present invention are used as described above. With a description being made from another viewpoint, a ground workpiece 1 is obtained when the grinding method according to one aspect of the present invention is performed. That is, a ground workpiece 1 is manufactured. In particular, there is manufactured a workpiece 1 of high quality which is not affected by variations in the processing result and the like that accompany the adjustment of the inclination of one of or both the table rotational axis 58 and the spindle 14a or 14b. Further, the manufactured ground workpiece 1 is thereafter divided and used to manufacture chips. The chips of high quality are obtained when the chips are manufactured by dividing the high-quality workpiece 1 manufactured by being ground by the grinding apparatus 2 and the grinding method.

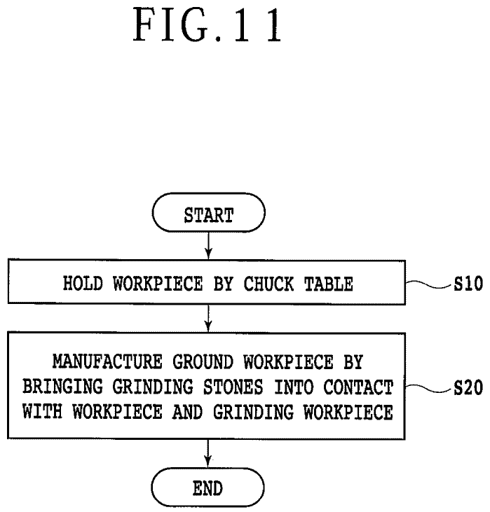

A procedure of a manufacturing method of manufacturing the ground workpiece 1 by grinding the workpiece 1 by the grinding apparatus 2 is no different from a procedure of the above-described grinding method according to one aspect of the present invention. Therefore, a description of the manufacturing method of manufacturing the ground workpiece 1 has practically been completed. In the following description, the procedure of the manufacturing method of manufacturing the ground workpiece 1 will be described for confirmation. However, the description of the method of grinding the workpiece 1 as described above is referred to as appropriate. FIG. 11 is a flowchart illustrating a flow of steps of the manufacturing method of manufacturing the ground workpiece 1.

The method of manufacturing the ground workpiece 1 illustrated in FIG. 11 first performs holding the workpiece 1 by the chuck table 8 by placing the workpiece 1 on the holding surface 8a of the chuck table 8 (S10, holding step).

Next, the ground workpiece 1 is manufactured by rotating the chuck table 8 about the table rotational axis 58 and rotating the spindle 14a or 14b, moving the chuck table 8 and the spindle 14a or 14b relative to each other in a direction of approaching each other, and thereby bringing the grinding stones 20a or 20b into contact with the workpiece 1 to grind the workpiece 1 (S20, grinding step). Here, when the workpiece 1 is ground by the grinding stones 20a or 20b being brought into contact with the workpiece 1, the thickness information of the workpiece 1 being ground is obtained.

Then, an adjustment amount necessary to adjust the inclination of one of or both the table rotational axis 58 and the spindle 14a or 14b is calculated as a necessary adjustment amount in reference to the obtained thickness information. In particular, the method of manufacturing the ground workpiece which method is illustrated in FIG. 11 calculates an actual adjustment amount by multiplying the necessary adjustment amount by an adjustment rate, and adjusts the inclination by the actual adjustment amount.

Incidentally, when the workpiece 1 is ground, the necessary adjustment amount is preferably calculated such that the PID control of the inclination of the adjustment target can be performed in reference to the thickness information obtained for the workpiece 1. Alternatively, the necessary adjustment amount is preferably calculated such that the P control of the inclination can be performed in reference to the thickness information. However, the method of calculating the necessary adjustment amount is not limited to the above. In addition, when the workpiece 1 is ground, the adjustment rate by which the necessary adjustment amount is to be multiplied is preferably determined in reference to the thickness information or the necessary adjustment amount. For example, the adjustment rate may be set to the first adjustment rate when a value indicating the thickness information or the necessary adjustment amount is higher than the selection threshold value, and the adjustment rate may be set to the second adjustment rate lower than the first adjustment rate when the value is equal to or less than the selection threshold value. At a time of the grinding, variations in the processing result and the like that accompany the adjustment of the inclination can be reduced by selecting a moderate adjustment rate such that the inclination can be adjusted at a moderate speed and such that repetition of adjustment and correction of the adjustment does not occur. Consequently, the ground workpiece 1 of high quality is obtained.

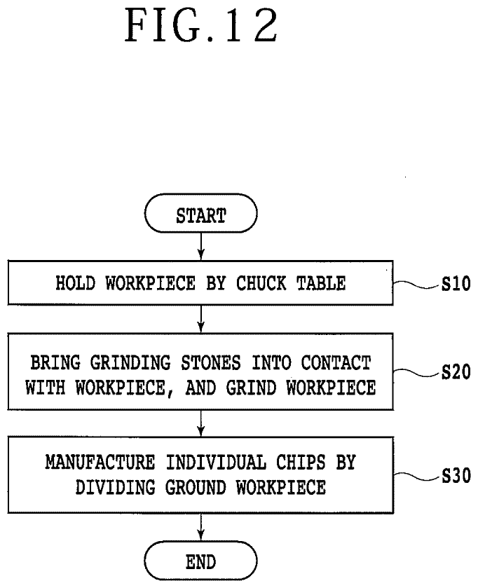

This ground workpiece 1 is taken out to the outside of the grinding apparatus 2, and divided. Chips can thereby be manufactured. In the following description, a procedure of a method of manufacturing the chips will be described. The description of the method of grinding the workpiece 1 and the method of manufacturing the ground workpiece 1 as described above is referred to as appropriate. FIG. 12 is a flowchart illustrating a flow of steps of the method of manufacturing chips.

The method of manufacturing illustrated in FIG. 12 first performs holding the workpiece 1 by the chuck table 8 by placing the workpiece 1 on the holding surface 8a of the chuck table 8 (S10, holding step).

Next, a ground workpiece 1 is manufactured by rotating the chuck table 8 about the table rotational axis 58 and rotating the spindle 14a or 14b, moving the chuck table 8 and the spindle 14a or 14b relative to each other in a direction of approaching each other, and bringing the grinding stones 20a or 20b into contact with the workpiece 1 to grind the workpiece 1 (S20, grinding step). Here, when the workpiece 1 is ground by the grinding stones 20a or 20b being brought into contact with the workpiece 1, the thickness information of the workpiece 1 being ground is obtained. Then, an adjustment amount necessary to adjust the inclination of one of or both the table rotational axis 58 and the spindle 14a or 14b is calculated as a necessary adjustment amount in reference to the obtained thickness information. In particular, the method of manufacturing chips which is illustrated in FIG. 12 calculates an actual adjustment amount by multiplying the necessary adjustment amount by an adjustment rate, and adjusts the inclination by the actual adjustment amount.

Incidentally, when the workpiece 1 is ground, the necessary adjustment amount is preferably calculated such that the PID control of the inclination of the adjustment target can be performed in reference to the thickness information obtained regarding the workpiece 1.

Alternatively, the necessary adjustment amount is preferably calculated such that the P control of the inclination can be performed in reference to the thickness information. However, the method of calculating the necessary adjustment amount is not limited to the above. In addition, when the workpiece 1 is ground, the adjustment rate by which the necessary adjustment amount is to be multiplied is preferably determined in reference to the thickness information or the necessary adjustment amount. For example, the adjustment rate may be set to the first adjustment rate when a value indicating the thickness information or the necessary adjustment amount is higher than the selection threshold value, and the adjustment rate may be set to the second adjustment rate lower than the first adjustment rate when the value is equal to or less than the selection threshold value.

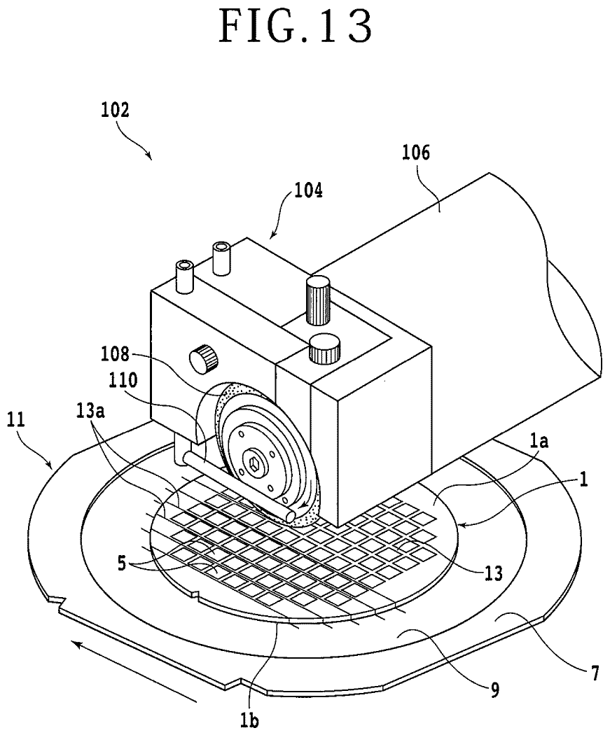

After completion of the grinding of the workpiece 1 in the grinding apparatus 2, the ground workpiece 1 is unloaded from the grinding apparatus 2, and is transferred to a processing apparatus that divides the workpiece 1. Here, before the workpiece 1 is loaded into the processing apparatus, the workpiece 1 is integrated with a sheet (adhesive tape) referred to as a dicing tape and an annular frame formed of a material such as metal. That is, there is formed a work unit in which the workpiece 1, the sheet, and the annular frame are integrated with each other. For example, the work unit is formed by fixing the sheet to the undersurface 1b side of the workpiece 1. FIG. 13 illustrates a perspective view schematically illustrating a work unit 11 formed by integrating the workpiece 1, an annular frame 7, and a sheet 9.

The annular frame 7 is formed of a metallic material such as aluminum or stainless steel. An opening portion is provided at the center of the annular frame 7. The opening portion penetrates the annular frame 7 from the top surface thereof to the undersurface thereof, and has a diameter larger than the diameter of the workpiece 1. The sheet 9 is fixed to the annular frame 7 in such a manner as to close the opening portion of the annular frame 7. The sheet 9 has a diameter larger than the diameter of the opening portion of the annular frame 7. The sheet 9 is, for example, an adhesive tape including a base material layer formed of a resin film or the like and an adhesive layer formed on one surface of the base material layer. The adhesive layer is, for example, preferably formed of ultraviolet curing resin or thermosetting resin. In this case, fixing force of the sheet 9 due to adhesive force of the adhesive layer can be decreased by irradiating the sheet 9 with ultraviolet rays or by heating the sheet 9. When the sheet 9 is affixed to the annular frame 7 in such a manner as to close the opening portion, the adhesive layer of the sheet 9 is exposed in the opening portion. Then, the workpiece 1 is affixed to the sheet 9 in the opening portion from the undersurface 1b side.

Incidentally, the sheet 9 may not include the adhesive layer. In that case, the sheet 9 not including the adhesive layer is fixed to the workpiece 1 by thermocompression bonding, for example, rather than being fixed to the undersurface 1b of the workpiece 1 by the adhesive force produced by the adhesive layer. Therefore, the sheet that does not include the adhesive layer and is fixed to the workpiece 1 by thermocompression bonding can be referred to also as a thermocompression bonding sheet.

After the work unit 11 is formed, the protective member 3 affixed to the top surface 1a of the workpiece 1 is peeled off. FIG. 13 schematically illustrates the workpiece 1 from which the protective member 3 has been peeled off to expose the top surface 1a side upward. As illustrated in FIG. 13, for example, a plurality of planned dividing lines 13 that intersect each other are set on the top surface 1a of the workpiece 1, and a device 5 is formed in each of regions demarcated by the planned dividing lines 13. A plurality of thin device chips (chips) each including the device 5 are manufactured by grinding and thinning the workpiece 1 having a plurality of devices 5 formed thereon from the undersurface 1b side and thereafter dividing the workpiece 1 along the planned dividing lines 13. The workpiece 1 is divided by, for example, a cutting apparatus having an annular cutting blade. The work unit 11 including the workpiece 1 is transferred to the cutting apparatus.

FIG. 13 is a perspective view schematically illustrating a manner in which a cutting apparatus 102 cuts the workpiece 1 to manufacture chips. The cutting apparatus 102 includes a cutting unit 104 that cuts the workpiece 1 and a chuck table (not illustrated) that holds the workpiece 1. The cutting unit 104 includes a cutting blade 108 including an annular grindstone portion and a spindle (not illustrated) whose distal end side is made to penetrate a central through hole of the cutting blade 108 and which rotates the cutting blade 108. The cutting blade 108 includes, for example, an annular base having a through hole at a center thereof and the annular grindstone portion provided to an outer circumferential portion of the annular base. A proximal end side of the spindle is connected to a spindle motor (not illustrated) housed within a spindle housing 106. The cutting blade 108 can be rotated by the spindle motor being actuated.

When the cutting blade 108 cuts the workpiece 1, heat is generated by friction between the cutting blade 108 and the workpiece 1. In addition, a cutting waste is produced from the workpiece 1 when the workpiece 1 is cut. Accordingly, in order to remove the heat and the cutting waste produced by the cutting, cutting water such as pure water is supplied to the cutting blade 108 and the workpiece 1 while the workpiece 1 is cut. The cutting unit 104 includes, for example, a cutting water supply nozzle 110 on a side of the cutting blade 108, the cutting water supply nozzle 110 supplying the cutting water to the cutting blade 108 and the like.

The method of manufacturing chips which is illustrated in FIG. 12 unloads the ground workpiece 1 from the grinding apparatus 2, and thereafter manufactures individual chips by dividing the workpiece 1 (S30, dividing step). For example, the workpiece 1 is divided by being cut by the cutting apparatus 102.

When the workpiece 1 is to be cut, the work unit 11 is placed on a chuck table (not illustrated), and the workpiece 1 is held on the chuck table via the sheet 9. Then, the chuck table is rotated to align the planned dividing lines 13 of the workpiece 1 with a processing feed direction of the cutting apparatus 102. In addition, the relative position of the chuck table and the cutting unit 104 is adjusted such that the cutting blade 108 is disposed above an extension of a planned dividing line 13. Next, the cutting blade 108 is rotated by the spindle being rotated. Then, the cutting unit 104 is lowered to a predetermined height position, and the chuck table and the cutting unit 104 are moved relative to each other along a direction parallel with the upper surface of the chuck table. Then, the grindstone portion of the rotating cutting blade 108 comes into contact with the workpiece 1 to cut the workpiece 1. A dividing groove 13a along the planned dividing line 13 is consequently formed in the workpiece 1.

After the cutting is performed along one planned dividing line 13, the chuck table and the cutting unit 104 are moved relative to each other in an indexing feed direction perpendicular to the processing feed direction, and the cutting of the workpiece 1 is similarly performed along another planned dividing line 13. After the cutting is performed along all of planned dividing lines 13 along one direction, the chuck table is rotated about an axis perpendicular to the holding surface, and the workpiece 1 is similarly cut along a planned dividing line 13 along another direction. When the workpiece 1 is cut along all of the planned dividing lines 13 of the workpiece 1, the division of the workpiece 1 is completed.

A plurality of chips formed by dividing the workpiece 1 continue to be fixed to the sheet 9. It is thus easy to handle the chips. The individual chips are thereafter peeled off the sheet 9. The method of manufacturing the chips which is illustrated in FIG. 12 manufactures the chips by dividing the workpiece 1 ground with high quality. Therefore, the manufactured chips are also of high quality.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A grinding apparatus for grinding a workpiece, the grinding apparatus comprising:
a chuck table having a holding surface capable of holding the workpiece, the chuck table being rotatable about a table rotational axis that penetrates a center of the holding surface;
a grinding unit including a spindle having a grinding wheel fitted to a lower end thereof such that a lower surface of the grinding wheel having annularly arranged grinding stones on the lower surface faces the holding surface of the chuck table, the grinding unit being configured to grind the workpiece held by the chuck table by the grinding stones of the grinding wheel;
a raising and lowering mechanism configured to raise and lower the spindle and the chuck table relative to each other;
an inclination adjusting unit configured to adjust inclination of one of or both the table rotational axis and the spindle;
a thickness measuring instrument configured to measure a thickness of the workpiece held by the chuck table; and
a controller;
the controller including
a grinding control section configured to bring the spindle and the chuck table close to each other by the raising and lowering mechanism while rotating the chuck table holding the workpiece about the table rotational axis and rotating the grinding wheel of the grinding unit about the spindle, bring the grinding stones into contact with the workpiece held by the chuck table, and make the grinding unit grind the workpiece,
a necessary adjustment amount calculating section configured to obtain thickness information of the workpiece being ground by the grinding unit, by using the thickness measuring instrument, and calculate an adjustment amount necessary for adjustment of the inclination, the adjustment being performed by the inclination adjusting unit, as a necessary adjustment amount, in reference to the thickness information,
an actual adjustment amount calculating section configured to calculate an actual adjustment amount by multiplying the necessary adjustment amount calculated by the necessary adjustment amount calculating section by an adjustment rate, and
an adjustment control section configured to adjust the inclination by the actual adjustment amount calculated by the actual adjustment amount calculating section, by controlling the inclination adjusting unit.

2. The grinding apparatus according to claim 1, wherein
the necessary adjustment amount calculating section calculates the necessary adjustment amount such that Proportional-Integral-Derivative control of the inclination is performed in reference to the thickness information.

3. The grinding apparatus according to claim 1, wherein
the necessary adjustment amount calculating section calculates the necessary adjustment amount such that Proportional control of the inclination is performed in reference to the thickness information.

4. The grinding apparatus according to claim 1, wherein
the actual adjustment amount calculating section determines the adjustment rate in reference to the thickness information or the necessary adjustment amount.

5. The grinding apparatus according to claim 1, wherein
the actual adjustment amount calculating section sets the adjustment rate to a first adjustment rate when a value indicating the thickness information or the necessary adjustment amount is higher than a selection threshold value, and sets the adjustment rate to a second adjustment rate lower than the first adjustment rate when the value is equal to or less than the selection threshold value.

6. A grinding method of grinding a workpiece in a grinding apparatus, the grinding apparatus including a chuck table having a holding surface capable of holding the workpiece, the chuck table being rotatable about a table rotational axis that penetrates a center of the holding surface, and a grinding unit including a spindle having a grinding wheel fitted to a lower end thereof, the grinding wheel having annularly arranged grinding stones on a lower surface thereof, the grinding method comprising:
holding the workpiece by the chuck table by placing the workpiece on the holding surface of the chuck table; and
grinding the workpiece by, after the holding, rotating the chuck table about the table rotational axis and rotating the spindle, moving the chuck table and the spindle relative to each other in a direction of approaching each other, and bringing the grinding stones into contact with the workpiece,
the grinding including obtaining thickness information of the workpiece being ground, calculating an adjustment amount necessary to adjust inclination of one of or both the table rotational axis and the spindle as a necessary adjustment amount in reference to the thickness information, calculating an actual adjustment amount by multiplying the necessary adjustment amount by an adjustment rate, and adjusting the inclination by the actual adjustment amount.

7. The grinding method according to claim 6, wherein
the grinding calculates the necessary adjustment amount such that Proportional-Integral-Derivative control of the inclination is allowed to be performed in reference to the thickness information.

8. The grinding method according to claim 6, wherein
the grinding calculates the necessary adjustment amount such that Proportional control of the inclination is allowed to be performed in reference to the thickness information.

9. The grinding method according to claim 6, wherein
the grinding determines the adjustment rate in reference to the thickness information or the necessary adjustment amount.

10. The grinding method according to claim 6, wherein
the grinding sets the adjustment rate to a first adjustment rate when a value indicating the thickness information or the necessary adjustment amount is higher than a selection threshold value, and sets the adjustment rate to a second adjustment rate lower than the first adjustment rate when the value is equal to or less than the selection threshold value.

11. A chip manufacturing method of manufacturing chips by grinding a workpiece in a grinding apparatus and dividing the workpiece, the grinding apparatus including a chuck table having a holding surface capable of holding the workpiece, the chuck table being rotatable about a table rotational axis that penetrates a center of the holding surface, and a grinding unit including a spindle having a grinding wheel fitted to a lower end thereof, the grinding wheel having annularly arranged grinding stones on a lower surface thereof, the chip manufacturing method comprising:
holding the workpiece by the chuck table by placing the workpiece on the holding surface of the chuck table;
grinding the workpiece by rotating the chuck table about the table rotational axis and rotating the spindle, moving the chuck table and the spindle relative to each other in a direction of approaching each other, and bringing the grinding stones into contact with the workpiece; and
manufacturing individual chips by unloading the ground workpiece from the grinding apparatus and dividing the ground workpiece,
when bringing the grinding stones into contact with the workpiece and grinding the workpiece, the method obtaining thickness information of the workpiece being ground, calculating an adjustment amount necessary to adjust inclination of one of or both the table rotational axis and the spindle as a necessary adjustment amount in reference to the thickness information, calculating an actual adjustment amount by multiplying the necessary adjustment amount by an adjustment rate, and adjusting the inclination by the actual adjustment amount.
